(19) United States
(12) Patent Application Publication
(10) Pub. No.: US 2026/0123136 A1
(43) Pub. Date: Apr. 30, 2026

(54) DISPLAY APPARATUS AND ELECTRONIC DEVICE INCLUDING THE SAME

(71) Applicant: Samsung Display Co., LTD., Yongin-si (KR)

(72) Inventors: Gyujeong LEE, Yongin-si (KR); Hyungil JEON, Yongin-si (KR); Changil TAE, Yongin-si (KR)

(21) Appl. No.: 19/094,856

(22) Filed: Mar. 29, 2025

(30) Foreign Application Priority Data
Oct. 30, 2024 (KR) 10-2024-0151506

(51) Int. Cl. H10H 29/49; G06F 3/041; G06F 3/044; G09G 3/32; H10H 29/01; H10H 29/41

(52) U.S. Cl. CPC H10H 29/49; G06F 3/0412; H10H 29/012; H10H 29/41; G06F 3/0446; G06F 2203/04103; G06F 2203/04107; G09G 3/32; G09G 2300/0426; G09G 2300/0819; G09G 2300/0842

(57) ABSTRACT

A display apparatus includes a plurality of island areas each arranged to be spaced apart from each other and a plurality of bridge areas connecting the plurality of island areas, a substrate, a pixel driving circuit portion arranged on the substrate, a first electrode pad arranged on the pixel driving circuit portion to be electrically connected to the pixel driving circuit portion, a second electrode pad arranged on the pixel driving circuit portion to be electrically connected to a power voltage, a first touch conductive layer arranged on the pixel driving circuit portion and including a first conductive pattern, and an inorganic light-emitting diode arranged on the first electrode pad and the second electrode pad.

This application claims priority to Korean Patent Application No. 10-2024-0151506, filed on Oct. 30, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a flexible display apparatus.

### 2. Description of the Related Art

With the development of display apparatuses for visually displaying electrical signals, various display apparatuses with excellent characteristics, such as small thickness, small weight, reduced power consumption, etc., have been introduced. For example, flexible display apparatuses which may be folded or rolled have been introduced. Recently, display apparatuses of various structures such as stretchable display apparatuses, which may be changed to have various shapes, have been actively researched and developed.

### SUMMARY

One or more embodiments include a display apparatus, for example, a flexible display apparatus. However, this objective is just an example and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a plurality of island areas each arranged to be spaced apart from each other and a plurality of bridge areas connecting the plurality of island areas, the display apparatus further including a substrate, a pixel driving circuit portion arranged on the substrate, a first electrode pad arranged on the pixel driving circuit portion to be electrically connected to the pixel driving circuit portion, a second electrode pad arranged on the pixel driving circuit portion to be electrically connected to a power voltage, a first touch conductive layer arranged on the pixel driving circuit portion and including a first conductive pattern, an inorganic light-emitting diode arranged on the first electrode pad and the second electrode pad, a first planarization layer arranged on the inorganic light-emitting diode, a first connection portion arranged on the first planarization layer and electrically connecting the inorganic light-emitting diode to the first electrode pad, a second connection portion arranged on the first planarization layer and electrically connecting the inorganic light-emitting diode to the second electrode pad, and a second touch conductive layer arranged on the first planarization layer to be electrically connected to the first touch conductive layer and including a second conductive pattern.

According to an embodiment, the first electrode pad, the second electrode pad, and the first touch conductive layer may be arranged on a same layer and may include a same material.

According to an embodiment, the first connection portion, the second connection portion, and the second touch conductive layer may be arranged on a same layer and may include a same material.

According to an embodiment, each of the first connection portion, the second connection portion, and the second touch conductive layer may pass through the first planarization layer.

According to an embodiment, the second touch conductive layer may be arranged in each of the plurality of island areas and the plurality of bridge areas.

According to an embodiment, the first touch conductive layer may be arranged in the plurality of island areas and is apart from the plurality of bridge areas.

According to an embodiment, the display apparatus may further include a first shielding layer arranged on a same layer as the first touch conductive layer and overlapping the second touch conductive layer arranged in the plurality of bridge areas.

According to an embodiment, the first shielding layer and the first touch conductive layer may include a same material.

According to an embodiment, the first touch conductive layer may be arranged in each of the plurality of island areas and the plurality of bridge areas.

According to an embodiment, the display apparatus may further include a second shielding layer arranged between the first touch conductive layer and the pixel driving circuit portion and overlapping the first touch conductive layer arranged in the plurality of island areas.

According to an embodiment, the first connection portion may include a first-1 connection portion overlapping the inorganic light-emitting diode in a plan view and including a transparent material and a first-2 connection portion electrically connecting the first-1 connection portion to the first electrode pad and including a same material as the second touch conductive layer.

According to an embodiment, the second connection portion may include a second-1 connection portion overlapping the inorganic light-emitting diode in a plan view and including a transparent material and a second-2 connection portion electrically connecting the second-1 connection portion to the second electrode pad and including a same material as the second touch conductive layer.

According to one or more embodiments, an electronic device includes a display apparatus which includes a plurality of island areas each arranged to be spaced apart from each other and a plurality of bridge areas connecting the plurality of island areas and is stretchable, the display apparatus further including a substrate, a pixel driving circuit portion arranged on the substrate, a first electrode pad arranged on the pixel driving circuit portion to be electrically connected to the pixel driving circuit portion, a second electrode pad arranged on the pixel driving circuit portion to be electrically connected to a power voltage, an inorganic light-emitting diode arranged on the first electrode pad and the second electrode pad, a first planarization layer arranged on the inorganic light-emitting diode, a first connection portion arranged on the first planarization layer and electrically connecting the inorganic light-emitting diode to the first electrode pad, a second connection portion arranged on the first planarization layer and electrically connecting the inorganic light-emitting diode to the second electrode pad, a first touch conductive layer arranged on the first planarization layer and including a first conductive pattern, a second planarization layer arranged on the first touch conductive layer, and a second touch conductive layer arranged on the second planarization layer to be electrically connected to the first touch conductive layer and including a second conductive pattern.

According to an embodiment, the first connection portion, the second connection portion, and the first touch conductive layer may be arranged on a same layer and may include a same material.

According to an embodiment, each of the first connection portion and the second connection portion may pass through the first planarization layer.

According to an embodiment, the second touch conductive layer may be arranged in each of the plurality of island areas and the plurality of bridge areas.

According to an embodiment, the first touch conductive layer may be arranged in the plurality of island areas and may be apart from the plurality of bridge areas.

According to an embodiment, the display apparatus may further include a first shielding layer arranged on a same layer as each of the first electrode pad and the second electrode pad and overlapping the second touch conductive layer arranged in the plurality of bridge areas.

According to an embodiment, the first shielding layer may include a same material as each of the first electrode pad and the second electrode pad.

According to an embodiment, the display apparatus may further include a third shielding layer arranged on a same layer as each of the first electrode pad and the second electrode pad and overlapping the first touch conductive layer arranged in the plurality of island areas.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIGS. 2A and 2B are perspective views of the display apparatus of FIG. 1 stretched in a first direction;

FIG. 2C is a perspective view of the display apparatus of FIG. 1 stretched in a second direction;

FIG. 2D is a perspective view of the display apparatus of FIG. 1 stretched in the first direction and the second direction;

FIG. 2E is a perspective view of the display apparatus of FIG. 1 stretched in a third direction;

FIG. 3 is a schematic plan view of a display apparatus according to an embodiment;

FIG. 4A is an enlarged plan view of a portion of a display apparatus, corresponding to region IV of FIG. 3, according to an embodiment;

FIG. 4B is an enlarged plan view of a portion of a display apparatus, corresponding to region IV of FIG. 3, according to an embodiment;

FIG. 4C is an enlarged plan view of a portion of a display apparatus, corresponding to region IV of FIG. 3, according to an embodiment;

FIG. 5 is a schematic cross-sectional view of a first island portion and a first bridge portion which are arranged in a display area of a display apparatus according to an embodiment;

FIGS. 6A to 6C are each an equivalent circuit diagram of a sub-pixel of a display apparatus according to an embodiment;

FIG. 7A is a schematic cross-sectional view of a light-emitting element of a display apparatus according to an embodiment;

FIG. 7B is a schematic cross-sectional view of a light-emitting element of a display apparatus according to an embodiment;

FIG. 8 is a diagram for describing an operation of a display apparatus according to an embodiment;

FIG. 9 is a schematic plan view of a touch unit of the display apparatus of FIG. 1 according to an embodiment;

FIG. 10A is a schematic enlarged plan view of a touch sensor included in a display apparatus according to an embodiment;

FIG. 10B is a view for describing an operation principle of a touch sensor included in a display apparatus according to an embodiment;

FIGS. 11A and 11B are schematic plan views of a display apparatus according to an embodiment;

FIG. 12 is a schematic cross-sectional view of a display apparatus according to an embodiment;

FIG. 13 is a schematic cross-sectional view of a display apparatus according to an embodiment;

FIG. 14 is a schematic cross-sectional view of a display apparatus according to an embodiment;

FIG. 15 is a schematic cross-sectional view of a display apparatus according to an embodiment;

FIGS. 16A to 16G are schematic perspective views of electronic devices each including a display apparatus according to an embodiment; and

FIG. 17 is a flow chart illustrating a method for fabricating a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

In the embodiments described hereinafter, the terms “first,” “second,” etc. are used to distinguish an element from another and are not used as a restrictive sense.

As used herein, the singular expressions are intended to include the plural forms as well, unless the context clearly indicates otherwise.

It will be further understood that the terms “comprises” or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

In the embodiments hereinafter, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

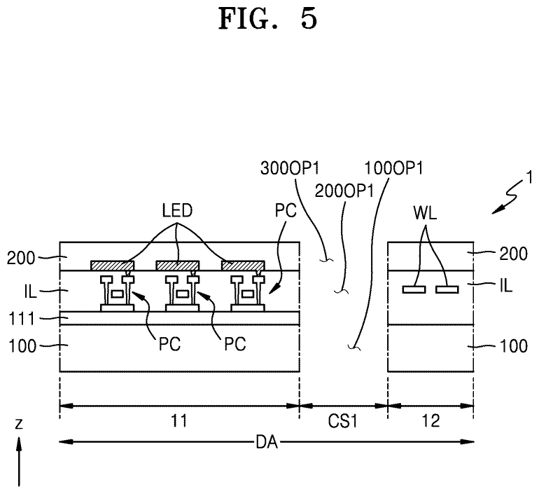

In this specification, the expression “a plan view” denotes a plane viewed in a direction perpendicular to a substrate 100 (see FIG. 5). That is, “A and B apart from each other in a plan view” denotes “A and B apart from each other when viewed in a direction perpendicular to the substrate 100 (see FIG. 5).”

In this specification, the expression “a cross-sectional view” denotes a plane in a direction perpendicular to the substrate 100 (see FIG. 5). That is, “A and B apart from each other in a cross-sectional view” denotes “A and B apart from each other when viewed in a plane in a direction perpendicular to the substrate 100 (see FIG. 5).”

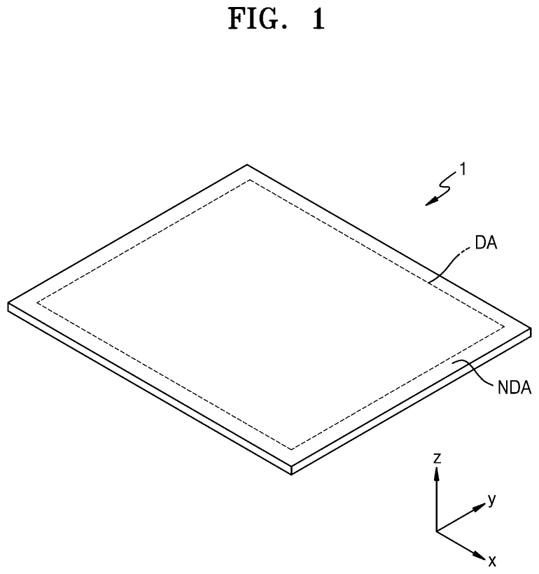

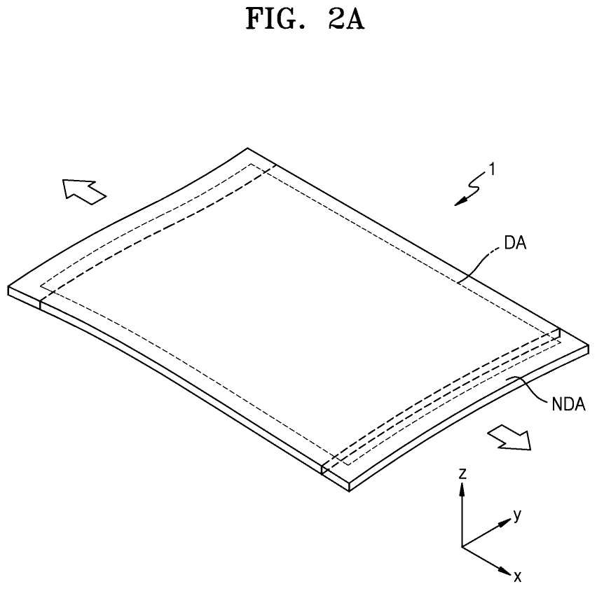

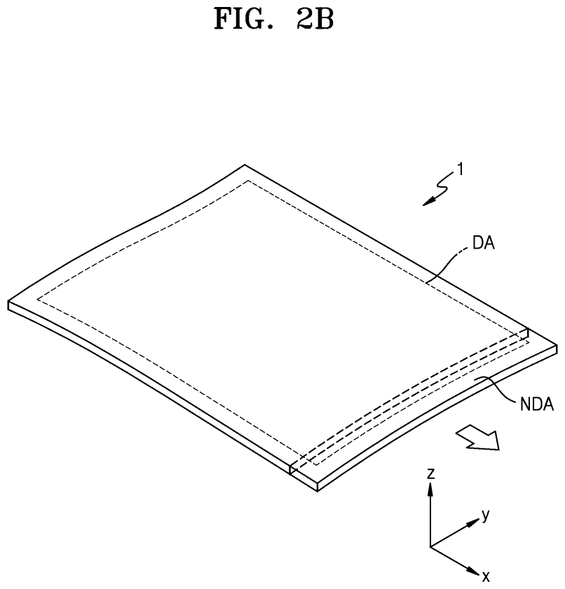

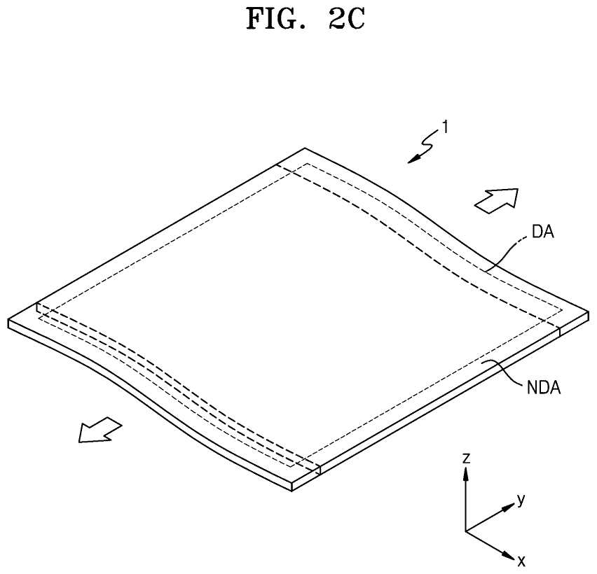

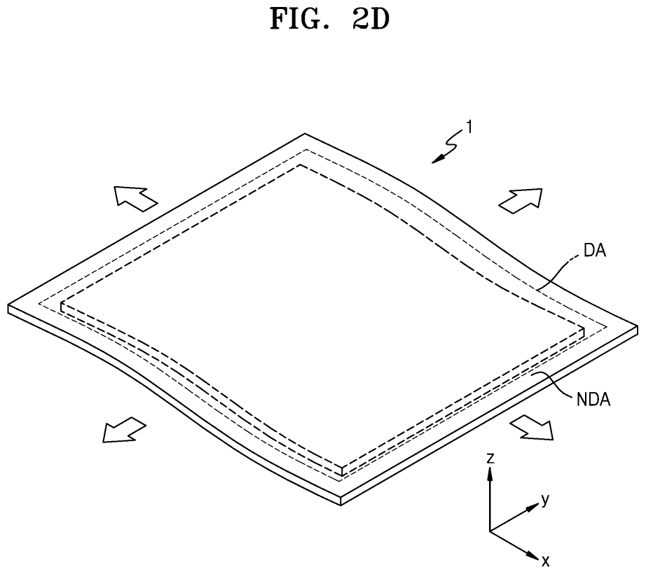

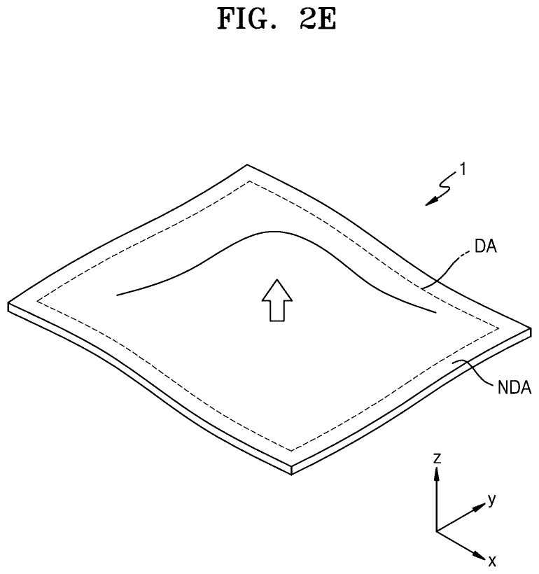

FIG. 1 is a schematic perspective view of a display apparatus 1 according to an embodiment. FIGS. 2A and 2B are perspective views showing the display apparatus 1 of FIG. 1 stretched in a first direction. FIG. 2C is a perspective view showing the display apparatus 1 of FIG. 1 stretched in a second direction. FIG. 2D is a perspective view showing the display apparatus 1 of FIG. 1 stretched in the first direction and the second direction. FIG. 2E is a perspective view showing the display apparatus 1 of FIG. 1 stretched in a third direction.

Referring to FIG. 1, the display apparatus 1 may include a display area DA and a non-display area NDA. The display area DA may include a plurality of pixels. The display apparatus 1 may provide a certain image by using light emitted from the plurality of pixels. The non-display area NDA may be arranged outside the display area DA. The non-display area NDA may entirely surround the display area DA.

The display apparatus 1 may be stretched or compressed in various directions. The display apparatus 1 may be stretched in the first direction (for example, an x direction and/or a −x direction) by an external force applied by an external object or a user. According to an embodiment, as illustrated in FIGS. 2A and 2B, the display area DA and/or the non-display area NDA of the display apparatus 1 may be stretched in the first direction (for example, the x direction and/or the −x direction). For example, the display area DA and/or the non-display area NDA of the display apparatus 1 may be stretched in the x direction and the −x direction as illustrated in FIG. 2A or may be stretched in the x direction with a side of the display apparatus 1 fixed as illustrated in FIG. 2B.

The display apparatus 1 may be stretched in the second direction (for example, a y direction and/or a −y direction) by an external force applied by an external object or a user. According to an embodiment, as illustrated in FIG. 2C, the display area DA and/or the non-display area NDA of the display apparatus 1 may be stretched in the y direction and the −y direction. According to another embodiment, the display area DA and/or the non-display area NDA of the display apparatus 1 may be stretched in the y direction or the −y direction with a side of the display apparatus 1 fixed.

The display apparatus 1 may be stretched in a plurality of directions, for example, the first direction (for example, the x direction and/or the −x direction) and the second direction (for example, the y direction and/or the −y direction), by an external force applied by an external object or a part of a human body. As illustrated in FIG. 2D, the display area DA and/or the non-display area NDA of the display apparatus 1 may be stretched in the ±x directions and the ±y directions.

The display apparatus 1 may be stretched in the third direction (for example, a z direction or a −z direction) by an external force applied by an external object or a part of a human body. According to an embodiment, FIG. 2E illustrates that a portion of the display apparatus 1, for example, a region of the display area DA, may protrude in the z direction. According to another embodiment, a portion of the display apparatus 1, for example, a region of the display area DA, may protrude in the −z direction (or may be recessed in the z direction).

FIGS. 2A to 2E illustrate that the display apparatus 1 may be stretched in the first direction, the second direction, and/or the third direction. However, the disclosure is not limited thereto. According to another embodiment, the display apparatus 1 may be variously changed to have an amorphous shape, such as a shape that is bent or twisted with respect to two or more axes, etc.

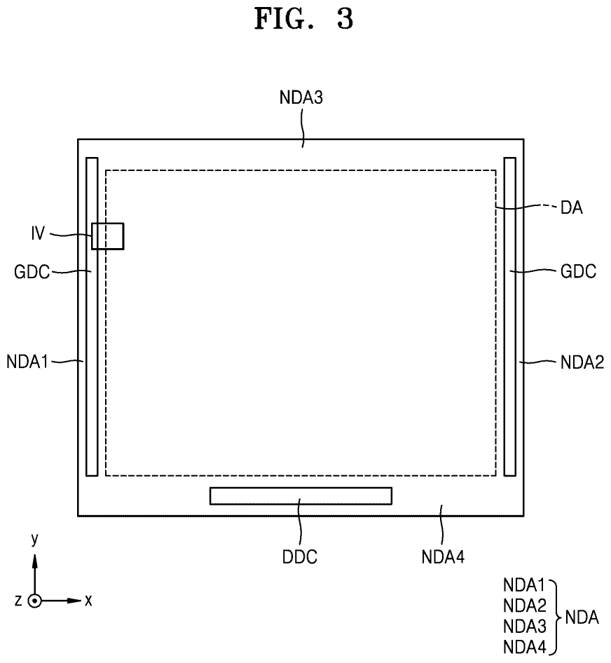

FIG. 3 is a schematic plan view of the display apparatus 1 according to an embodiment.

A plurality of pixels may be arranged in the display area DA of the display apparatus 1. Each pixel may include sub-pixels emitting light of different colors. A light-emitting element corresponding to each sub-pixel may be arranged in the display area DA. Circuits configured to provide electrical signals to the light-emitting elements and transistors electrically connected to the light-emitting elements, the light-emitting elements and the transistors being arranged in the display area DA, may be arranged in the non-display area NDA around the display area DA. A gate driving circuit GDC may be arranged in each of a first non-display area NDA1 and a second non-display area NDA2 that are respectively arranged at both sides of the display area DA. The gate driving circuit GDC may include drivers configured to provide electrical signals to gate electrodes respectively included in the transistors electrically connected to the light-emitting elements. FIG. 3 illustrates that the gate driving circuit GDC may be arranged in each of the first non-display area NDA1 and the second non-display area NDA2. However, the disclosure is not limited thereto. According to another embodiment, the gate driving circuit GDC may be arranged in any one of the first non-display area NDA1 and the second non-display area NDA2.

A data driving circuit DDC may be arranged in a third non-display area NDA3 and/or a fourth non-display area NDA4 connecting the first non-display area NDA1 with the second non-display area NDA2. According to an embodiment, FIG. 3 illustrates that the data driving circuit DDC may be arranged in the fourth non-display area NDA4. According to another embodiment, the data driving circuit DDC may be arranged in each of the third non-display area NDA3 and the fourth non-display area NDA4.

FIG. 3 illustrates that the data driving circuit DDC may be arranged in the fourth non-display area NDA4 of the display apparatus 1. However, the disclosure is not limited thereto. According to another embodiment, the display apparatus 1 may further include a flexible circuit board (not shown) electrically connected thereto through a terminal portion (not shown) arranged in the fourth non-display area NDA4, and the data driving circuit DDC may be arranged on the flexible circuit board described above.

According to some embodiments, an elongation rate of the non-display area NDA may be less than or equal to an elongation rate of the display area DA. According to an embodiment, the elongation rate of the non-display area NDA may be different for each area of the non-display area NDA. For example, the first non-display area NDA1, the second non-display area NDA2, and the third non-display area NDA3 may have substantially the same elongation rate, while the fourth non-display area NDA4 may have an elongation rate which is less than the elongation rate of each of the first non-display area NDA1, the second non-display area NDA2, and the third non-display area NDA3.

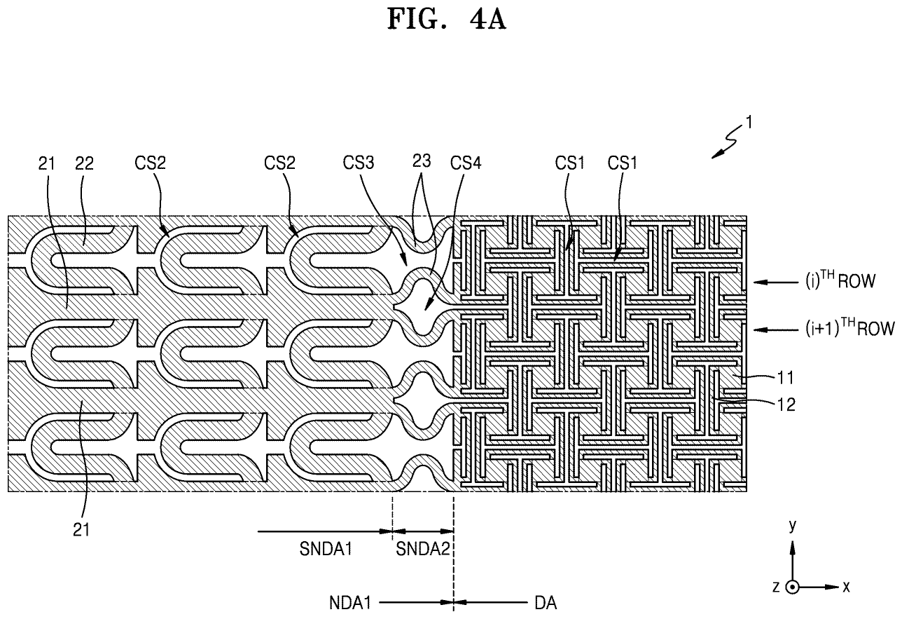

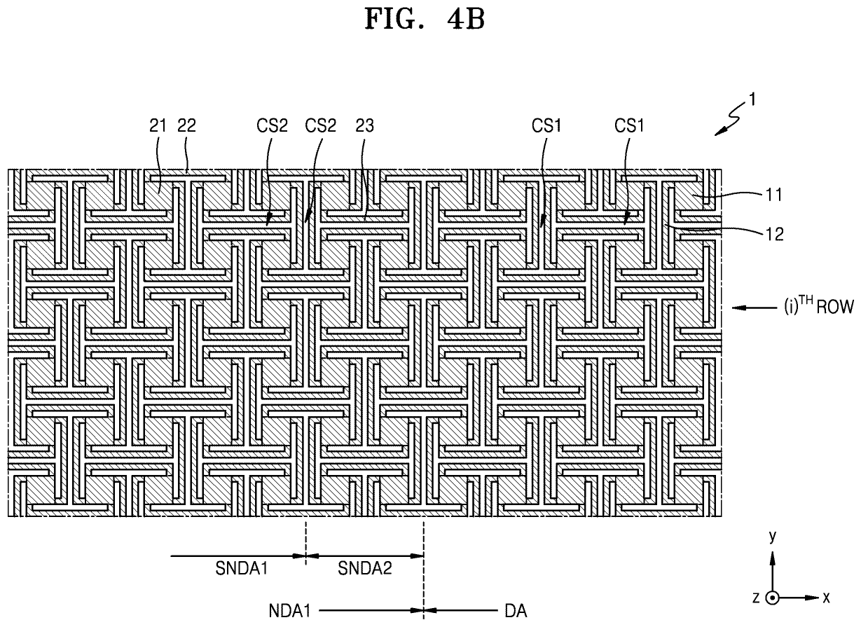

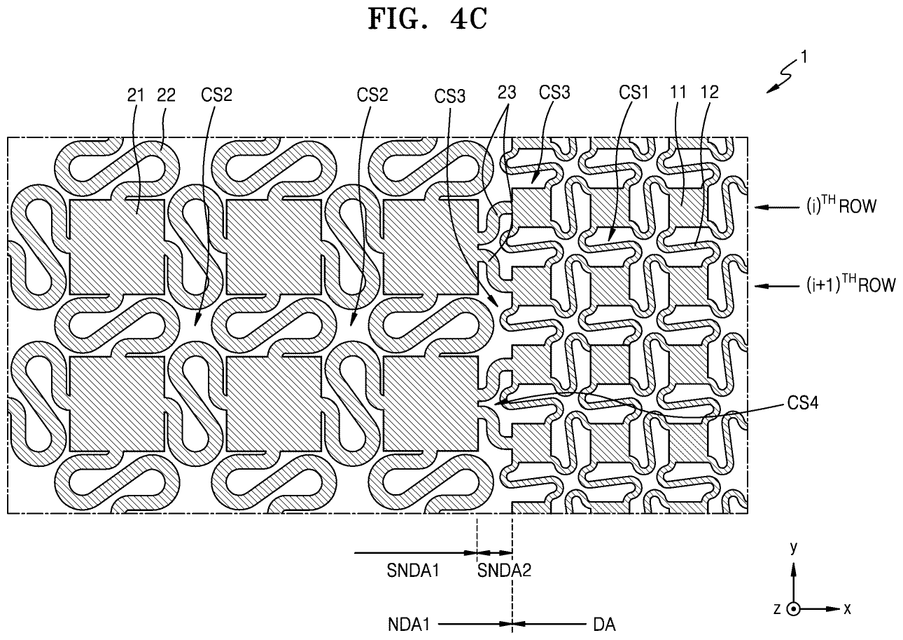

FIG. 4A is an enlarged plan view of a portion of the display apparatus 1 corresponding to region IV of FIG. 3, according to an embodiment.

Referring to FIG. 4A, the display apparatus 1 may include first island portions 11 and first bridge portions 12 in the display area DA, wherein the first island portions 11 may be apart from each other in a first direction (for example, an x direction or an −x direction) and a second direction (for example, a y direction or a −y direction), and the first bridge portions 12 may connect the first island portions 11 that are adjacent to each other.

Each first island portion 11 may be connected to the plurality of first bridge portions 12. For example, each first island portion 11 may be connected to four first bridge portions 12. Two first bridge portions 12 may be arranged at both sides of the first island portion 11 in the first direction (for example, the x direction or the −x direction), and the rest two first bridge portions 12 may be arranged at both sides of the first island portion 11 in the second direction (for example, the y direction or the −y direction). According to an embodiment, four first bridge portions 12 may be connected to four sides of the first island portion 11, respectively. Each of the four first bridge portions 12 may be adjacent to each corner of the first island portion 11.

The first bridge portions 12 may be spaced apart from each other by a first opening portion CS1 located between the first bridge portions 12. According to an embodiment, the first opening portion CS1 having an approximately H shape and the first opening portion CS1 having an approximately I shape rotated by 90 degrees from the H shape may be alternately and repeatedly arranged in the first direction (for example, the x direction or the −x direction) and the second direction (for example, the y direction or the −y direction), respectively. Both ends of each first bridge portion 12 may be connected to each first island portion 11 adjacent thereto, wherein a side of each first bridge portion 12 may be spaced apart from a side of the first island portion 11 adjacent thereto and/or a side of another first bridge portion 12 by the first opening portion CS1.

The display apparatus 1 may include, for example, second island portions 21 apart from each other and second bridge portions 22 connecting the second island portions 21 adjacent to each other in the non-display area NDA, for example, the first non-display area NDA1 illustrated in FIG. 4A.

Each second island portion 21 may extend in the first direction (for example, the x direction or the −x direction). The second island portions 21 may be apart from each other in the second direction (for example, the y direction or the −y direction) crossing the first direction (for example, the x direction or the −x direction). Each second island portion 21 may include drivers of the gate driving circuit GDC (see FIG. 2) described with reference to FIG. 3.

The second bridge portions 22 may have a serpentine shape. The length of the second bridge portion 22 may be greater than a least distance between the second island portions 21 adjacent to each other in the second direction (for example, the y direction or the −y direction). According to an embodiment, the second bridge portion 22 may have an approximately “Ω” shape that is convex toward the first direction (for example, the x direction or the −x direction). The second bridge portions 22 may be arranged between the second island portions 21 adjacent to each other and may be apart from each other.

The second bridge portions 22 between the second island portions 21 adjacent to each other may be spaced apart from each other by a second opening portion CS2. The second opening portions CS2 and the second bridge portions 22 may be alternately arranged in the first direction (for example, the x direction or the −x direction) between the second island portions 21 adjacent to each other. The second opening portions CS2 may have substantially the same shapes. Both ends of each second bridge portion 22 may be connected to each second island portion 21 adjacent thereto, wherein a side of each second bridge portion 22 may be spaced apart from a side of the second island portion 21 adjacent thereto and/or a side of another second bridge portion 22 by the second opening portion CS2.

Any one second island portion 21 arranged in the first non-display area NDA1 may correspond to the first island portions 11 in a plurality of rows arranged in the display area DA. For example, any one second island portion 21 arranged in the first non-display area NDA1 may correspond to the first island portions 11 in an (i)^{th} row of the display area DA and the first island portions 11 in an (i+1)^{th} row of the display area DA (here, i is a positive number that is greater than 0). FIG. 4A illustrates that one second island portion 21 corresponds to two rows of the first island portions 11. However, the disclosure is not limited thereto. According to another embodiment, any one second island portion 21 arranged in the first non-display area NDA1 may correspond to n rows of the first island portions 11 arranged in the display area DA (here, n is a positive number greater than or equal to 3).

The non-display area NDA, for example, the first non-display area NDA1, may include a first sub-non-display area SNDA1 in which the second island portions 21 and the second bridge portions 22 described above are arranged and a second sub-non-display area SNDA2 arranged between the first sub-non-display area SNDA1 and the display area DA. Third bridge portions 23 for connecting the display area DA with the first sub-non-display area SNDA1 may be arranged in the second sub-non-display area SNDA2. An end of the third bridge portion 23 may be connected to the second island portion 21 and/or the second bridge portion 22, and the other end of the third bridge portion 23 may be connected to the first island portion 11 and/or the first bridge portion 12.

The third bridge portions 23 may have a serpentine shape. According to an embodiment, the shape of the third bridge portions 23 may be different from the shape of each of the first bridge portions 12 and the second bridge portions 22. According to an embodiment, as illustrated in FIG. 4A, the third bridge portion 23 may have an approximately “Ω” shape that is convex toward the second direction (for example, the y direction or the −y direction). One of the third bridge portions 23 arranged in the second direction (for example, the y direction or the −y direction) and adjacent to each other may be convex in the y direction and the other may be convex in the −y direction, so that the third bridge portions 23 may have a symmetrical structure. Third opening portions CS3 and fourth opening portions CS4 having different shapes from each other may be repeatedly arranged between the third bridge portions 23. The width of the third bridge portion 23 may be different from the width of the first bridge portion 12 and the width of the second bridge portion 22. According to an embodiment, the width of the third bridge portion 23 may be greater than the width of the first bridge portion 12 and may be less than the width of the second bridge portion 22.

FIG. 4A illustrates that the second island portion 21 and the second bridge portion 22 of the non-display area NDA, for example, the first non-display area NDA1, may have different shapes from the first island portion 11 and the first bridge portion 12 of the display area DA, respectively. According to another embodiment, the second island portion 21 and the second bridge portion 22 of the non-display area NDA may have substantially the same shapes as the first island portion 11 and the first bridge portion 12 of the display area DA, respectively.

FIG. 4B is an enlarged plan view of a portion of the display apparatus 1, corresponding to region IV of FIG. 3, according to an embodiment.

Referring to FIG. 4B, the display apparatus 1 may include the first island portions 11 and the first bridge portions 12 in the display area DA, wherein the first island portions may be apart from each other, and the first bridge portions 12 may connect the first island portions 11 spaced apart from each other by the first opening portion CS1 but adjacent to each other. The structure of the display area DA of FIG. 4B may be substantially the same as the structure of the display area DA described above with reference to FIG. 4A.

The display apparatus 1 may include the second island portions 21 and the second bridge portions 22 arranged in the non-display area NDA, for example, the first non-display area NDA1. According to an embodiment, the second island portions 21 and the second bridge portions 22 may have substantially the same shapes as the first island portions 11 and the first bridge portions 12, respectively.

The second island portions 21 may be apart from each other in the first direction (for example, the x direction or the −x direction) and the second direction (for example, the y direction or the −y direction) in the non-display area NDA, for example, the first non-display area NDA1. Each of the second bridge portions 22 may connect the second island portions 21 adjacent to each other. The second bridge portions 22 may each be spaced apart from each other by the second opening portion CS2 located between the second bridge portions 22.

The second opening portion CS2 may have substantially the same shape as the first opening portion CS1. For example, the second opening portion CS2 having an approximately H shape and the second opening portion CS2 having an approximately I shape may be alternately and repeatedly arranged in the non-display area NDA, for example, the first non-display area NDA1. Both ends of each second bridge portion 22 may be connected to each second island portion 21 adjacent thereto, wherein a side of each second bridge portion 22 may be spaced apart from a side of the second island portion 21 adjacent thereto and/or a side of another second bridge portion 22 by the second opening portion CS2.

Each second island portion 21 may be connected to four second bridge portions 22. Each second island portion 21 may include drivers of the gate driving circuit GDC (see FIG. 2) described with reference to FIG. 3.

The second island portions 21 in any row arranged in the first non-display area NDA1 may correspond to the first island portions 11 in any row arranged in the display area DA. For example, the second island portions 21 arranged in an (i)^{th} row in the first direction (for example, the x direction or the −x direction) in the first non-display area NDA1 may correspond to the first island portions 11 arranged in the same row, for example, the (i)^{th} row, in the display area DA (here, i is a positive number greater than 0).

The display apparatus 1 may include the third bridge portions 23 arranged in the second sub-non-display area SNDA2 for connecting the display area DA with the first sub-non-display area SNDA1. The non-display area NDA, for example, the first non-display area NDA1, may include the first sub-non-display area SNDA1 in which the second island portions 21 and the second bridge portions 22 are arranged and the second sub-non-display area SNDA2 including the third bridge portions 23 and arranged between the first sub-non-display area SNDA1 and the display area DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of a portion of the display apparatus 1, corresponding to region IV of FIG. 3, according to an embodiment.

Referring to FIG. 4C, the display apparatus 1 may include the first island portions 11 and the first bridge portions 12 in the display area DA, wherein the first island portions 11 may be apart from each other in the first direction (for example, the x direction or the −x direction) and the second direction (for example, the y direction or the −y direction), and the first bridge portions 12 may connect the first island portions 11 that are adjacent to each other.

The first bridge portions 12 may be arranged to be spaced apart from each other by the first opening portion CS1 located between the first bridge portions 12. The first bridge portions 12 may have a serpentine shape. For example, as illustrated in FIG. 4C, the first bridge portions 12 may approximately have a shape of the alphabet letter “S.”

Each first island portion 11 may be connected to the plurality of first bridge portions 12. For example, each first island portion 11 may be connected to four first bridge portions 12. Two first bridge portions 12 may be arranged at both sides of the first island portion 11 in the first direction (for example, the x direction or the −x direction), and the rest two first bridge portions 12 may be arranged at both sides of the first island portion 11 in the second direction (for example, the y direction or the −y direction). The four first bridge portions 12 may be connected to four sides of the first island portion 11, respectively. Each of the four first bridge portions 12 may be adjacent to each corner of the first island portion 11.

The display apparatus 1 may include the second island portions 21 and the second bridge portions 22 in the non-display area NDA, for example, the first non-display area NDA1 illustrated in FIG. 4C, wherein the second island portions 21 may be apart from each other in the first direction (for example, the x direction or the −x direction) and the second direction (for example, the y direction or the −y direction), and the second bridge portions 22 may connect the second island portions 21 that are adjacent to each other.

The second bridge portions 22 may each be arranged to be spaced apart from each other by the second opening portion CS2 located between the second bridge portions 22. The second bridge portions 22 may have a serpentine shape. For example, as illustrated in FIG. 4C, the second bridge portions 22 may approximately have a shape of the alphabet letter “S.” The size and/or the width of the second bridge portion 22 may be different from the size and/or the width of the first bridge portion 12. For example, the size and/or the width of the second bridge portion 22 may be greater than the size and/or the width of the first bridge portion 12. The radius of curvature of a round portion of the second bridge portion 22 may be different from the radius of curvature of a round portion of the first bridge portion 12. For example, the radius of curvature of the round portion of the second bridge portion 22 may be greater than the radius of curvature of the round portion of the first bridge portion 12.

Each second island portion 21 may be connected to the plurality of second bridge portions 22. Each second island portion 21 may be connected to four second bridge portions 22. Two second bridge portions 22 may be arranged at both sides of the second island portion 21 in the first direction (for example, the x direction or the −x direction), and the rest two second bridge portions 22 may be arranged at both sides of the second island portion 21 in the second direction (for example, the y direction or the −y direction). According to an embodiment, four second bridge portions 22 may be connected to four sides of the second island portion 21, respectively. Each second bridge portion 22 may be connected to a central portion of each side of the second island portion 21.

The second island portions 21 in any row arranged in the first non-display area NDA1 may correspond to the first island portions 11 in a plurality of rows arranged in the display area DA. For example, the second island portions 21 in any row arranged in the first non-display area NDA1 may correspond to the first island portions 11 in an (i)^{th} row of the display area DA and the first island portions 11 in an (i+1)^{th} row of the display area DA (here, i is a positive number that is greater than 0). According to another embodiment, the second island portions 21 in any row may correspond to the first island portions 11 in n rows (here, n is a positive number that is greater than or equal to 3).

The non-display area NDA, for example, the first non-display area NDA1, may include the first sub-non-display area SNDA1 in which the second island portions 21 and the second bridge portions 22 described above are arranged and the second sub-non-display area SNDA2 arranged between the first sub-non-display area SNDA1 and the display area DA. The third bridge portions 23 for connecting the display area DA with the first sub-non-display area SNDA1 may be arranged in the second sub-non-display area SNDA2. A first end of the third bridge portion 23 may be connected to the second island portion 21, and a second end of the third bridge portion 23 may be connected to the first island portion 11. For example, the first end of the third bridge portion 23 may be connected to a central portion of a side of the second island portion 21, and the second end of the third bridge portion 23 may be connected to a central portion of a side of the first island portion 11.

The third bridge portions 23 may have a serpentine shape. According to an embodiment, the shape of the third bridge portions 23 may be different from the shape of each of the first bridge portions 12 and the second bridge portions 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. The third opening portion CS3 and the fourth opening portion CS4 having different shapes from each other may be alternately arranged in the second direction (for example, the y direction or the −y direction) between the third bridge portions 23.

FIG. 5 is a schematic cross-sectional view of the first island portion 11 and the first bridge portion 12 which are arranged in the display area DA of the display apparatus 1 according to an embodiment.

Referring to FIG. 5, the first island portion 11 and the first bridge portion 12 which are arranged in the display area DA may be spaced apart from each other with the first opening portion CS1 disposed therebetween. The first island portion 11 may include light-emitting elements LED and a circuit electrically connected to the light-emitting elements LED and configured to drive the light-emitting elements LED, for example, a pixel driving circuit portion PC. Also, the first bridge portion 12 may include lines WL electrically connected to the pixel driving circuit portions PCs respectively arranged in the first island portions 11 that are adjacent to each other.

With respect to the first island portion 11, a buffer layer 111 including an inorganic insulating material may be arranged on the substrate 100, and the pixel driving circuit portion PC may be arranged on the buffer layer 111. An insulating layer IL including an inorganic insulating material and/or an organic insulating material may be arranged between the pixel driving circuit portion PC and the light-emitting element LED. The light-emitting element LED may be arranged on the insulating layer IL and may be electrically connected to the corresponding pixel driving circuit portion PC. The light-emitting elements LED may emit light of different colors from each other or light of the same color as each other. According to an embodiment, each light-emitting element LED may emit red, green, or blue light. According to some embodiments, the light-emitting elements LED may emit white light. According to another embodiment, each light-emitting element LED may emit red, green, blue, or white light.

The substrate 100 may include polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. According to an embodiment, the substrate 100 may include a single layer including the polymer resins described above. According to another embodiment, the substrate 100 may have a multi-layered structure including a base layer including the polymer resins described above and a barrier layer including an inorganic insulating material. The substrate 100 including the polymer resins may be flexible, rollable, or bendable.

According to an embodiment, FIG. 5 illustrates that three pixel driving circuit portions PCs are arranged in each first island portion 11, wherein three light-emitting elements LEDs are connected to the three pixel driving circuits PCs, respectively. However, the disclosure is not limited thereto. According to another embodiment, the numbers of pixel driving circuit portions PCs and light-emitting elements LEDs arranged in the first island portion 11 may be one, two, or four or more.

A touch unit 200 may be arranged on the insulating layer IL and the light-emitting element LED and may sense an external input applied from the outside.

With respect to the first bridge portion 12, an insulating layer IL including an organic insulating material may be arranged on the substrate 100. When the display apparatus 1 is stretched, the first bridge portion 12, which is relatively more changed than the first island portion 11, may not include a layer including an inorganic insulating material, for which cracks may easily occur, unlike the first island portion 11.

According to an embodiment, the substrate 100 corresponding to the first bridge portion 12 may have a stack structure substantially the same as the stack structure of the substrate 100 corresponding to the first island portion 11. According to an embodiment, the substrate 100 corresponding to the first bridge portion 12 and the substrate 100 corresponding to the first island portion 11 may include polymer resin layers formed together in the same process. According to another embodiment, the substrate 100 corresponding to the first bridge portion 12 may have a stack structure different from the stack structure of the substrate 100 corresponding to the first island portion 11. According to some embodiments, the substrate 100 corresponding to the first island portion 11 may have a multi-layered structure including a base layer including polymer resins and a barrier layer including an inorganic insulating material, and the substrate 100 corresponding to the first bridge portion 12 may have a structure including polymer resin layers and not including a layer including an inorganic insulating material.

As described above, the lines WL of the first bridge portion 12 may include signal lines (for example, gate lines, data lines, etc.) configured to provide an electrical signal to a transistor included in the pixel driving circuit portion PC of the first island portion 11 or voltage lines (for example, driving voltage lines, initialization voltage lines, etc.) configured to provide a voltage to the transistor included in the pixel driving circuit portion PC of the first island portion 11.

Referring to FIGS. 4A to 4C and 5, the substrate 100 corresponding to the first island portion 11 and the substrate 100 corresponding to the first bridge portion 12 may be connected to each other. In other words, the plan views of FIGS. 4A to 4C above may be substantially the same as a plan view of the substrate 100 of FIG. 5. In other words, the substrate 100 may include an area corresponding to the first island portion 11, an area corresponding to the first bridge portion 12, and an opening 100OP1 having the same shape as the first opening portion CS1.

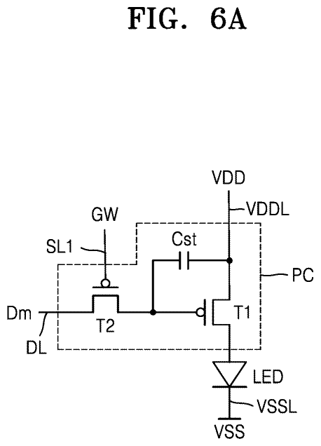

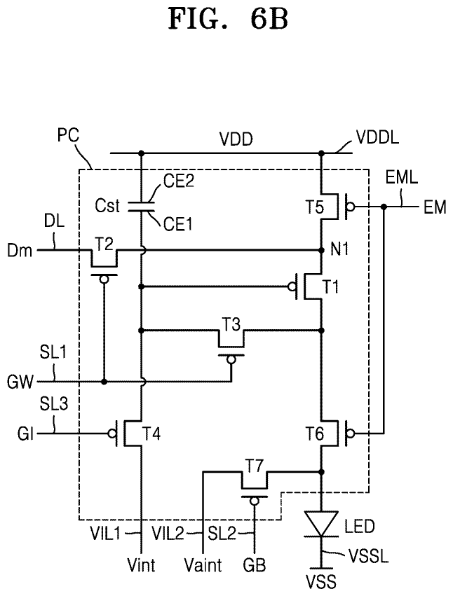

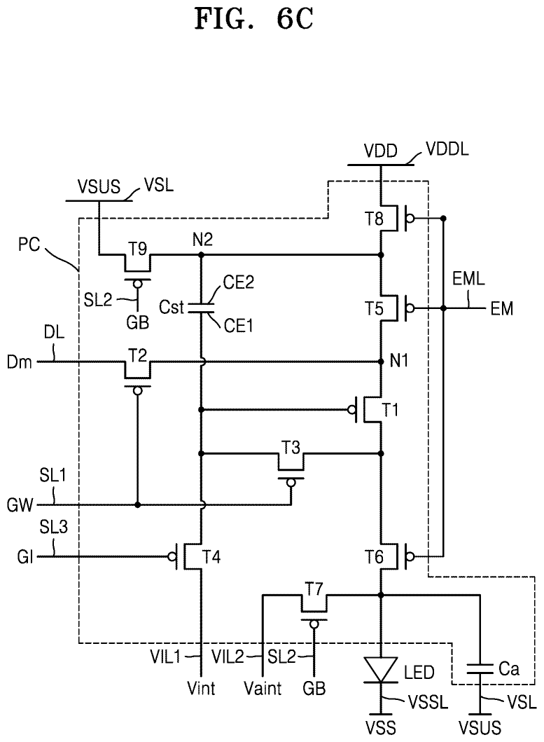

FIGS. 6A to 6C are each an equivalent circuit diagram of a sub-pixel of the display apparatus 1 according to an embodiment.

Referring to FIG. 6A, the light-emitting element LED corresponding to the sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to signal lines and voltage lines. The signal lines may include a gate line such as a first scan line SL1, and a data line DL, and the voltage lines may include a first voltage line VDDL.

The second transistor T2 may be electrically connected to the first scan line SL1 and the data line DL. The first scan line SL1 may be configured to provide a first scan signal GW1 to a gate electrode of the second transistor T2. The second transistor T2 may be configured to transmit a data signal Dm input from the data line DL to the first transistor T1, according to the first scan signal GW1 input from the first scan line SL1.

The storage capacitor Cst may be electrically connected to the second transistor T2 and the first voltage line VDDL and may be configured to store a voltage corresponding to the difference between a voltage transmitted from the second transistor T2 and a first power voltage VDD supplied by the first voltage line VDDL.

The first transistor T1 may include a driving transistor and may be configured to control a driving current flowing through the light-emitting element LED. The first transistor T1 may be connected to the first voltage line VDDL and the storage capacitor Cst. The first transistor T1 may be configured to control the driving current flowing from the first voltage line VDDL to the light-emitting element LED according to a value of the voltage stored in the storage capacitor Cst. The light-emitting element LED may emit light having a certain brightness according to the driving current. A first electrode of the light-emitting element LED may be electrically connected to the first transistor T1, and a second electrode of the light-emitting element LED may be electrically connected to a second voltage line VSSL configured to supply a second power voltage VSS.

FIG. 6A illustrates that the pixel driving circuit portion PC may include two transistors and one storage capacitor. However, according to another embodiment, the pixel driving circuit portion PC may include three or more transistors.

Referring to FIG. 6B, the pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC may be electrically connected to signal lines and voltage lines. The signal lines may include gate lines, such as a first scan line SL1, a second scan line SL2, a third scan line SL3, a fourth scan line SL4, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing the first electrode of the light-emitting element LED to the pixel driving circuit portion PC.

The first transistor T1 may be electrically connected to the first voltage line VDDL through the fifth transistor T5 and may be electrically connected to the light-emitting element LED through the sixth transistor T6. The first transistor T1 may function as a driving transistor and may be configured to receive a data signal Dm and transmit a driving current to the light-emitting element LED according to a switching operation of the second transistor T2.

The second transistor T2 may include a data write transistor and may be electrically connected to the first scan line SL1 and the data line DL. The second transistor T2 may be electrically connected to the first voltage line VDDL through the fifth transistor T5. The second transistor T2 may be turned on according to a first scan signal GW received through the first scan line SL1 and may be configured to perform a switching operation of transmitting the data signal Dm transmitted through the data line DL to a first node N1.

The third transistor T3 may be electrically connected to the first scan line SL1 and may be electrically connected to the light-emitting element LED through the sixth transistor T6. The third transistor T3 may be turned on according to the first scan signal GW received through the first scan line SL1 and may diode-connect the first transistor T1.

The fourth transistor T4 may include a first initialization transistor and may be electrically connected to the third scan line SL3 and the first initialization voltage line VIL1. The fourth transistor T4 may be turned on according to a third scan signal GI received through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5 may include an operation control transistor and the sixth transistor T6 may include an emission control transistor. The fifth transistor T5 and the sixth transistor T6 may be electrically connected to the emission control line EML and may be simultaneously turned on according to an emission control signal EM transmitted through the emission control line EML to form a current path through which a driving current may flow from the first voltage line VDDL in a direction toward the light-emitting element LED.

The seventh transistor T7 may include a second initialization transistor and may be electrically connected to the second scan line SL2, the second initialization voltage line VIL2, and the sixth transistor T6. The seventh transistor T7 may be turned on according to a second scan signal GB transmitted through the second scan line SL2 and may be configured to transmit the second initialization voltage Vaint from the second initialization voltage line VIL2 to the first electrode of the light-emitting element LED to initialize the first electrode of the light-emitting element LED.

The storage capacitor Cst may include a first electrode CE1 and the second electrode CE2. The first electrode CE1 may be electrically connected to the gate electrode of the first transistor T1, and the second electrode CE2 may be electrically connected to the first voltage line VDDL. The storage capacitor Cst may be configured to store and sustain a voltage corresponding to the difference between a voltage of the first voltage line VDDL and a voltage of the gate electrode of the first transistor T1, so as to sustain a voltage applied to the gate electrode of the first transistor T1.

Referring to FIG. 6C, the pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit portion PC may be electrically connected to signal lines and voltage lines. The signal lines may include gate lines, such as a first scan line SL1, a second scan line SL2, a third scan line SL3, a fourth scan line SL4, and an emission control line EML, and a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing the first electrode of the light-emitting element LED to the pixel driving circuit portion PC. The sustaining voltage line VSL may be configured to provide a sustaining voltage VSUS to a second node N2, for example, a second electrode CE2 of the storage capacitor Cst, in an initialization section and a data write section.

The first transistor T1 may be electrically connected to the first voltage line VDDL through the fifth transistor T5 and the eighth transistor T8 and may be electrically connected to the light-emitting element LED through the sixth transistor T6. The first transistor T1 may function as a driving transistor and may be configured to receive a data signal Dm and transmit a driving current to the light-emitting element LED according to a switching operation of the second transistor T2.

The second transistor T2 may be electrically connected to the first scan line SL1 and the data line DL and may be electrically connected to the first voltage line VDDL through the fifth transistor T5 and the eighth transistor T8. The second transistor T2 may be turned on according to a first scan signal GW received through the first scan line SL1 and may be configured to perform a switching operation of transmitting the data signal Dm transmitted through the data line DL to a first node N1.

The third transistor T3 may be electrically connected to the first scan line SL1 and may be electrically connected to the light-emitting element LED through the sixth transistor T6. The third transistor T3 may be turned on according to the first scan signal GW received through the first scan line SL1 and may be configured to diode-connect the first transistor T1 to compensate for a threshold voltage of the first transistor T1.

The fourth transistor T4 may be electrically connected to the third scan line SL3 and the first initialization voltage line VIL1 and may be turned on according to a third scan signal GI received through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5, the sixth transistor T6, and the eighth transistor T8 may be electrically connected to the emission control line EML and may be simultaneously turned on according to an emission control signal EM received through the emission control line EML to form a current path through which a driving current may flow from the first voltage line VDDL toward the light-emitting element LED.

The seventh transistor T7 may include a second initialization transistor and may be electrically connected to the second scan line SL2, the second initialization voltage line VIL2, and the sixth transistor T6. The seventh transistor T7 may be turned on according to a second scan signal GB received through the second scan line SL2 and may be configured to transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the sustaining voltage line VSL. The ninth transistor T9 may be turned on according to the second scan signal GB transmitted through the second scan line SL2 and may be configured to transmit the sustaining voltage VSUS to a second node N2, for example, the second electrode CE2 of the storage capacitor Cst, in an initialization section and a data write section.

Each of the eighth transistor T8 and the ninth transistor T9 may be electrically connected to the second node N2, for example, the second electrode CE2 of the storage capacitor Cst. According to some embodiments, in the initialization section and the data write section, the eighth transistor T8 may be turned off and the ninth transistor T9 may be turned on, and in an emission section, the eighth transistor T8 may be turned on and the ninth transistor T9 may be turned off. The sustaining voltage VSUS may be transmitted to the second node N2 in the initialization section and the data write section, and thus, the uniformity of the brightness (for example, the long range uniformity (LRU)) of the display apparatus according to a voltage drop of the first voltage line VDDL may be improved.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustaining voltage line VSL, and the first electrode of the light-emitting element LED. The auxiliary capacitor Ca may be configured to store and sustain a voltage corresponding to the difference between voltages of the first electrode of the light-emitting element LED and the sustaining voltage line VSL, while the seventh transistor T7 and the ninth transistor T9 are being turned on, and thus, the auxiliary capacitor Ca may prevent an increase in black brightness when the sixth transistor T6 is turned off.

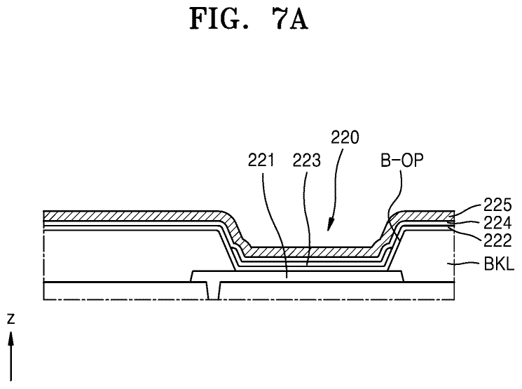

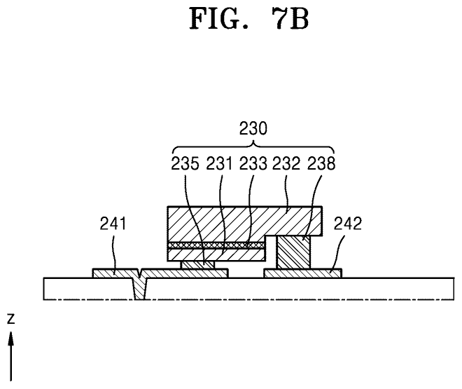

FIG. 7A is a schematic cross-sectional view of a light-emitting element of the display apparatus 1 according to an embodiment.

Referring to FIG. 7A, the light-emitting element according to an embodiment may include an organic light-emitting diode 220 including an organic material. The organic light-emitting diode 220 may include a first electrode 221 arranged on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first electrode 221 may include a reflective layer including Ag, Mg, Al, Pt, Pd, Au, Ni, Nd, Ir, Cr, or a compound thereof. According to another embodiment, the first electrode 221 may further include a layer including ITO, IZO, ZnO, AZO or In₂O₃ above/below the reflective layer described above.

The emission layer 223 may include a high or low molecular-weight organic material emitting light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a transparent (semi-transparent) layer including Ag, Mg, Al, Pt, Pd, Au, Ni, Nd, Ir, Cr, Li, Ca, or an alloy thereof. Alternatively, the second electrode 225 may further include a layer, such as ITO, IZO, ZnO, AZO, or In₂O₃, on the transparent (semi-transparent) layer including the material described above.

FIG. 7B is a schematic cross-sectional view of a light-emitting element of the display apparatus 1 according to an embodiment.

Referring to FIG. 7B, the light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, which are arranged on the same layer.

According to some embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with a p-type dopant, such as Mg, Zn, Ca, Sr, Ba, and the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with an n-type dopant, such as Si, Ge, Sn, and the like.

The intermediate layer 233 may be where electrons and holes reunite, and when the electrons and the holes reunite, transition to a reduced energy level may be performed to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, and 0≤x+y≤1) and may be formed as a single quantum well structure or a multi-quantum well (MQW) structure. Also, the intermediate layer 233 may include a quantum wire structure or a quantum dot structure.

It is described with reference to FIG. 7B that the first semiconductor layer 231 may include the p-type semiconductor layer and the second semiconductor layer 232 may include the n-type semiconductor layer. However, the disclosure is not limited thereto. According to another embodiment, the first semiconductor layer 231 may include the n-type semiconductor layer and the second semiconductor layer 232 may include the p-type semiconductor layer.

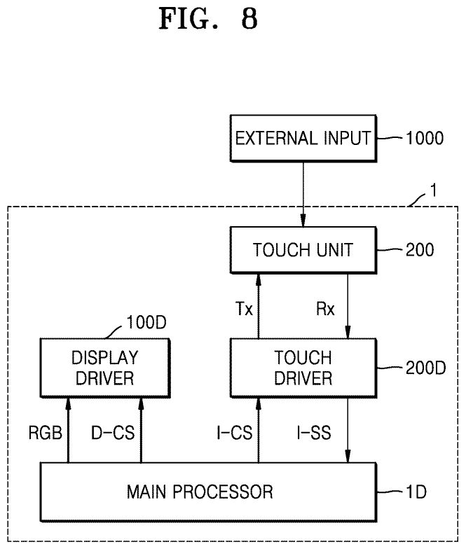

FIG. 8 is a diagram for describing an operation of the display apparatus 1 according to an embodiment.

Referring to FIG. 8, the display apparatus 1 may include the touch unit 200, a display driver 100D, a touch driver 200D, and a main processor 1D.

The touch unit 200 may sense an external input 1000 applied from the outside. The external input 1000 may include suitable input devices that may provide a capacitance change. For example, the touch unit 200 may sense an input by not only an input device of a passive type, such as a human body of a user, but also an input device of an active type providing a driving signal.

The main processor 1D may control general operations of the display apparatus 1. For example, the main processor 1D may control operations of the display driver 100D and the touch driver 200D. The main processor 1D may include at least one microprocessor and may further include a graphics controller. The main processor 1D may be referred to as an application processor, a central processing device, or a main driver.

The display driver 100D may receive image data RGB and a control signal D-CS from the main processor 1D. The control signal D-CS may include various signals. For example, the control signal D-CS may include an input vertical synchronization signal, an input horizontal synchronization signal, a main clock, a data enable signal, etc. The display driver 100D may generate a vertical synchronization signal and a horizontal synchronization signal for controlling timing to provide a signal to a display panel based on the control signal D-CS.

The touch driver 200D may drive the touch unit 200. The touch driver 200D may receive a control signal I-CS from the main processor 1D. The control signal I-CS may include a mode determination signal for determining a driving mode of the touch driver 200D and a clock signal.

The touch driver 200D may apply a touch driving signal Tx to the touch unit 200, in response to the control signal I-CS received from the main processor 1D. The touch driver 200D may apply the touch driving signal Tx having a predetermined driving frequency to the touch unit 200.

The touch driver 200D may receive a touch sensing signal Rx from the touch unit 200 and may convert the touch sensing signal Rx into a digital signal. The touch driver 200D may calculate coordinate information of an input, based on the touch sensing signal Rx received from the touch unit 200 and may provide a coordinate signal I-SS having the coordinate information to the main processor 1D. The main processor 1D may execute an operation corresponding to a user input, based on the coordinate signal I-SS. For example, the main processor 1D may operate the display driver 100D so that a new application image may be displayed on a display panel.

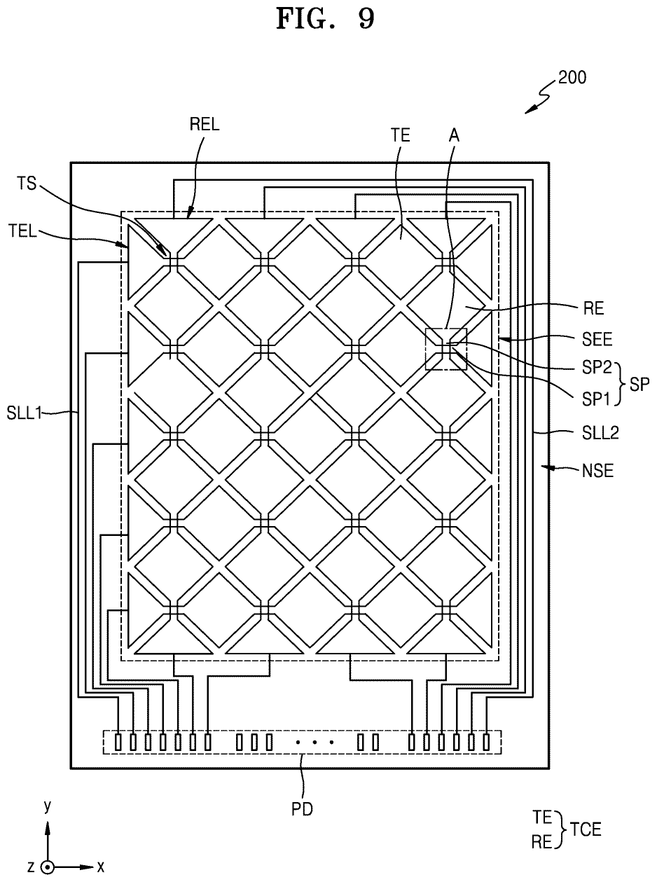

FIG. 9 is a schematic plan view of the touch unit 200 of the display apparatus 1 of FIG. 1.

FIG. 9 illustrates the touch unit 200 configured to operate by forming an electrical signal in response to a user's touch. According to an embodiment, the touch unit 200 may include an electrostatic capacitive type. According to an embodiment, the touch unit 200 may include a mutual capacitive type.

The touch unit 200 may include a touch sensor TS including a touch electrode TCE. The touch unit 200 may include a plurality of touch electrodes TCE. The plurality of touch electrodes TCE may be electrically connected to each other through connection patterns SP. First and second signal lines SLL1 and SLL2 connecting the plurality of touch electrodes TCE to an external touch driver through a pad portion PD may further be provided in an external area of the plurality of touch electrodes TCE.

The plurality of touch electrodes TCE may include driving electrodes TE formed to be connected to each other in a first direction (for example, an x-axis direction) and sensing electrodes RE arranged to be distributed between the driving electrodes TE so as not to overlap the driving electrodes TE and formed to be connected to each other in a second direction (for example, a y-axis direction) perpendicular to the first direction (for example, the x-axis direction). The driving electrodes TE and the sensing electrodes RE may be alternately arranged in the distributed manner not to overlap each other.

The first direction (for example, the x-axis direction) in which the driving electrodes TE are connected to each other and the second direction (for example, the y-axis direction) in which the sensing electrodes RE are connected to each other may be different directions crossing each other. For example, when the first direction (for example, the x-axis direction) is set to be a row direction, the second direction (for example, the y-axis direction) may be set to be a column direction.

That is, the driving electrodes TE may be arranged in a plural number along each of column lines and/or each of row lines, and the driving electrodes TE located in the same column line or the row line (in the present embodiment, the same row line) may be formed to be connected to each other in the first direction (for example, the x-axis direction) by first connection patterns SP1 arranged in a plural number along the same column line or the same row line. The form in which the plurality of driving electrodes TE are connected to each other in the same column line or row line may be referred to as a driving electrode line TEL. For example, one driving electrode line TEL may extend in the first direction (for example, the x-axis direction), and the plurality of driving electrode lines TEL may be arranged in the second direction (for example, the y-axis direction). The driving electrode lines TEL in each line may be connected to the first signal line SLL1 corresponding to the driving electrode lines TEL. The first signal line SLL1 may be configured to transmit a touch driving signal Tx applied from the touch driver 200D of FIG. 8 to the driving electrodes TE of the touch unit 200. That is, the touch driving signal Tx may be applied to the driving electrodes TE through the first signal lines SLL1.

The sensing electrodes RE may be arranged in a plural number along each of row lines and/or each of column lines, and the sensing electrodes RE located in the same row line or the column line (in the embodiment, the same column line) may be formed to be connected to each other in the second direction (for example, the y-axis direction) by second connection patterns SP2 arranged in a plural number along the same row line or the same column line. The form in which the plurality of sensing electrodes RE are connected to each other in the same column line or row line may be referred to as a sensing electrode line REL. For example, one sensing electrode line REL may extend in the second direction (for example, the y-axis direction), and the plurality of sensing electrode lines REL may be arranged in the first direction (for example, the x-axis direction). The sensing electrode lines REL in each line may be connected to the second signal line SLL2 corresponding to the sensing electrode lines REL. The second signal line SLL2 may be configured to transmit the touch sensing signal Rx described with reference to FIG. 8 to the touch driver 200D. That is, the touch driver 200D may be electrically connected to the sensing electrodes RE through the second signal lines SLL2 and may receive the touch sensing signal Rx from the sensing electrodes RE. The touch sensing signal Rx may be configured to reflect a capacitance change amount between the driving electrodes TE and the sensing electrodes RE.

The connection patterns SP may include the plurality of first connection patterns SP1 formed in plural in the first direction (for example, the x-axis direction) and connecting the driving electrodes TE to each other in the first direction (for example, the x-axis direction) and the plurality of second connection patterns SP2 formed in plural in the second direction (for example, the y-axis direction) and connecting the sensing electrodes RE to each other in the second direction (for example, the y-axis direction). The connection patterns SP may include a transparent electrode material or a non-transparent low-resistance electrode material, while a thickness, a width, etc. thereof may be adjusted to prevent the visibility thereof.

The first signal line SLL1 and the second signal line SLL2 may be respectively electrically connected to the driving electrodes TE and the sensing electrodes RE in each line, the driving electrodes TE being connected to each other in the first direction (for example, the x-axis direction) and the sensing electrodes RE being connected to each other in the second direction (for example, the y-axis direction), and the first signal line SLL1 and the second signal line SLL2 may respectively connect the driving electrodes TE and the sensing electrodes RE to an external touch driving circuit, such as the touch driver 100D described with reference to FIG. 8, through the pad portion PD. The first and second signal lines SLL1 and SLL2 may be located primarily in a touch non-active area NSE defined outside the touch active area SEE not to overlap the touch active area SEE in which an image is displayed, and may have a wide range of material selection to include not only a transparent electrode material used to form the touch electrodes TCE, but also a low resistive material, such as Mo, Ag, Ti, Cu, Al, Mo/Al/Mo, etc.

FIG. 9 illustrates that the first and second connection patterns SP1 and SP2 cross each other according to an embodiment. However, the disclosure is not necessarily limited thereto. For example, the first connection patterns SP1 may connect the driving electrodes TE to each other in the first direction while not crossing the second connection patterns SP2 by detouring along a path overlapping the adjacent sensing electrodes RE. In this case, an insulating layer for obtaining stability may be arranged between the first connection patterns SP1 and the sensing electrodes RE.

The touch unit 200 having the structure as described above may measure a capacitance changing between the driving electrodes TE and the sensing electrodes RE, when an input device, such as a finger, approaches or contacts the touch unit 200, and thus, may detect a touch position.

Each of the plurality of driving electrodes TE and the plurality of sensing electrodes RE may be arranged as a structure in which a plurality of consecutive polygons having a diamond shape are connected, but is not limited thereto. Shapes, sizes, or arrangement forms of the plurality of driving electrodes TE and the plurality of sensing electrodes RE may be variously changed according to, for example, a shape or a size of a display area in which a pixel is arranged or a sensing method.

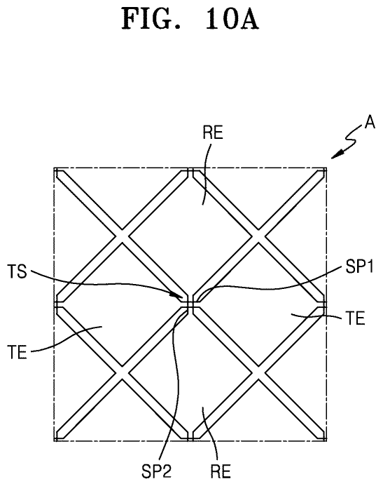

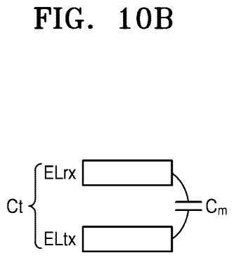

FIG. 10A is a schematic enlarged plan view of the touch sensor TS included in the display apparatus 1 (see FIG. 8) according to an embodiment, and FIG. 10B is a view for describing an operation principle of the touch sensor TS included in the display apparatus 1 (see FIG. 8) according to an embodiment.

The touch sensor TS may correspond to a portion at which the driving electrode line TEL and the sensing electrode line REL described with reference to FIG. 9 cross each other. The touch sensor TS may correspond to a portion at which the first connection pattern SP1 and the second connection pattern SP2 cross each other, as illustrated in FIG. 10A. The touch sensor TS may correspond to a portion at which the first connection pattern SP1 and the second connection pattern SP2 overlap each other.

Referring to FIG. 10A, the driving electrodes TE may be arranged at right and left sides of the touch sensor TS, respectively, and the sensing electrodes RE may be arranged above and below the touch sensor TS, respectively. The touch sensor TS may sense whether or not there is a touch input, through the driving electrodes TE and the sensing electrodes RE located around the touch sensor TS.

In detail, referring to FIG. 10B, the touch sensor TS may include a touch capacitor Ct. The touch capacitor Ct may include a first electrode ELtx and a second electrode ELrx. The first electrode ELtx may correspond to the driving electrodes TE arranged at the right and left sides of the touch sensor TS, respectively, and the second electrode ELrx may correspond to the sensing electrodes RE arranged above and below the touch sensor TS, respectively.

The touch capacitor Ct including the first electrode ELtx and the second electrode ELrx may have a touch capacitance Cm. The touch capacitor Ct may have the touch capacitance Cm by being charged between the driving electrode TE and the sensing electrode RE according to the touch driving signal Tx having a certain driving frequency. The touch capacitance Cm between the first electrode ELtx and the second electrode ELrx may be referred to as a mutual capacitance. In other words, the touch capacitor Ct may have a mutual touch capacitance Cm between the driving electrode TE and the sensing electrode RE. When there is no touch input applied to the display apparatus 1, the capacitance Cm may not change and may maintain a previous value. When there is a touch input (for example, a finger touch) applied to the touch sensor TS or a position adjacent to the touch sensor TS, a capacitance may be formed between the first electrode ELtx or the second electrode ELrx and the finger, and thus, the capacitance Cm between the first electrode ELtx and the second electrode ELrx may change. As described above, when an arbitrary touch input is applied to the display apparatus, the capacitance Cm may change, and the touch sensor TS may sense whether or not there is a touch input, by using the capacitance change amount between the first electrode ELtx and the second electrode ELrx.

According to an embodiment, the driving frequency of the touch driving signal Tx may be determined based on touch capacitance data and data of the touch capacitance change amount.

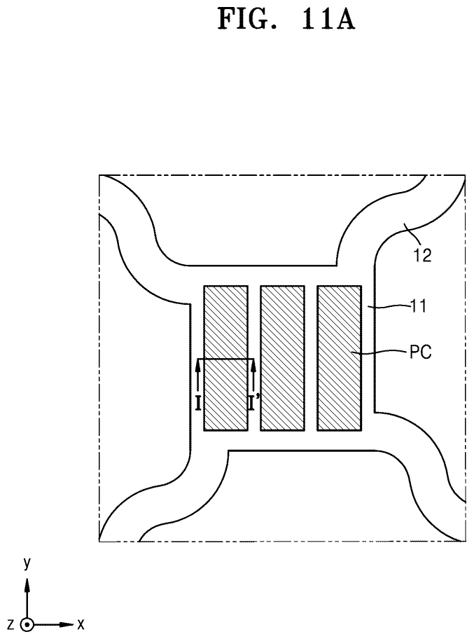

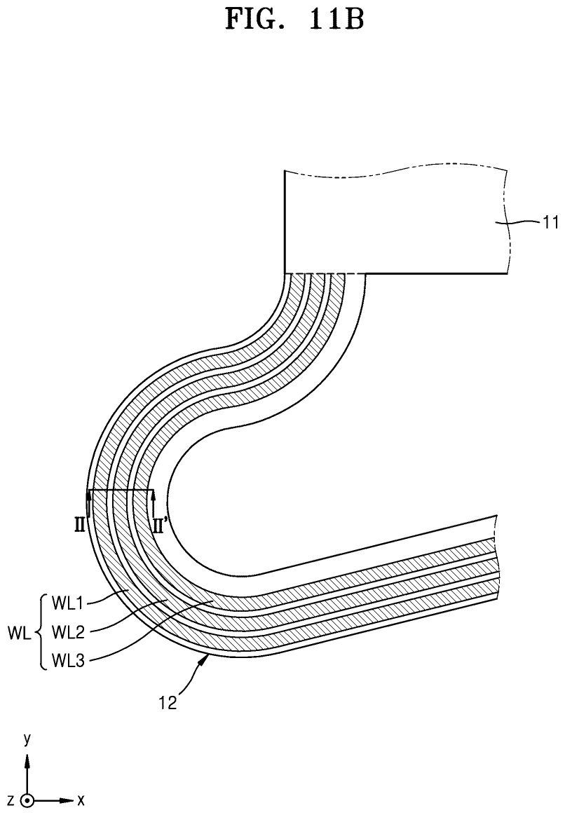

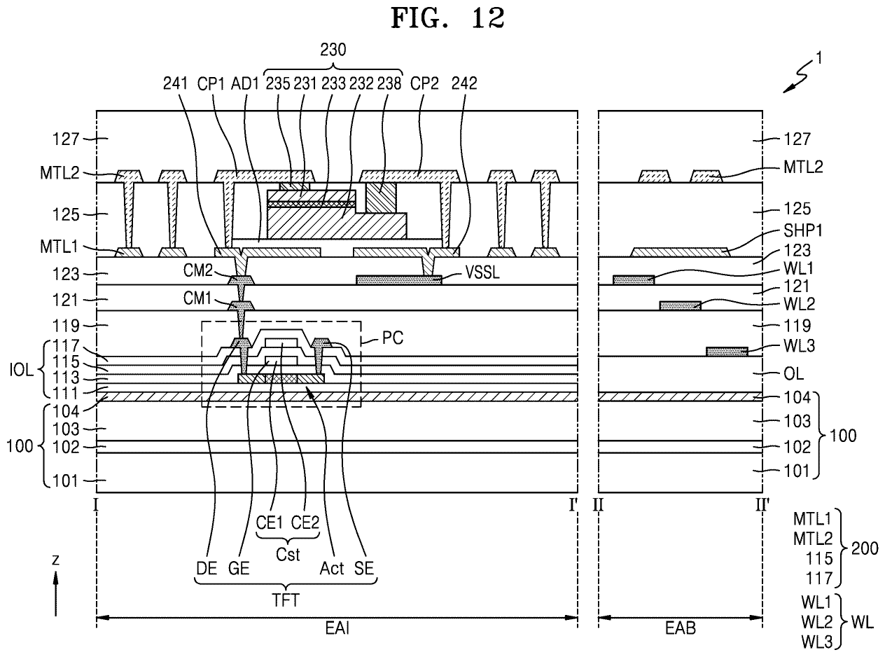

FIGS. 11A and 11B are schematic plan views of the display apparatus 1 according to an embodiment, and FIG. 12 is a schematic cross-sectional view of the display apparatus 1 according to an embodiment.

In detail, FIG. 12 is the cross-sectional view of the display apparatus 1, taken along line I-I′ of FIG. 11A and line II-II′ of FIG. 11B.

Referring to FIGS. 11A to 12, the display apparatus 1 may include a plurality of island portions and a plurality of bridge portions. The plurality of island portions may include at least one of the plurality of first island portions 11 (see FIGS. 4A to 4C) and the plurality of second island portions 21 (see FIGS. 4A to 4C). The plurality of bridge portions may include at least one of the plurality of first bridge portions 12 (see FIGS. 4A to 4C) and the plurality of second bridge portions 22 (see FIGS. 4A to 4C).

Also, the display apparatus 1 may include a plurality of island areas EAI arranged to be apart from each other and a plurality of bridge areas EAB connecting the plurality of island areas EAI. The plurality of island areas EAI may be where the plurality of island portions are arranged in the display apparatus 1. The plurality of bridge areas EAB may be where the plurality of bridge portions are arranged in the display apparatus 1.

Hereinafter, it is assumed that the plurality of island portions refer to the plurality of first island portions 11 (see FIGS. 4A to 4C) and the plurality of bridge portions refer to the plurality of first bridge portions 12 (see FIGS. 4A to 4C).

Referring to FIG. 11A, the first island portion 11 arranged in the display area DA may include the light-emitting elements and the pixel driving circuit portion PC electrically connected to the light-emitting elements. The pixel driving circuit portion PC may include transistors and at least one capacitor as described above. FIG. 11A illustrates that three pixel driving circuit portions PC are arranged in the first island portion 11. However, the disclosure is not limited thereto. According to another embodiment, the numbers of pixel driving circuit portions PCs and light-emitting elements LEDs arranged in the first island portion 11 may be one, two, or four or more.

Referring to FIG. 12, the substrate 100 corresponding to the island area EAI may include a first base layer 101, a first barrier layer 102, a second base layer 103, and a second barrier layer 104. Each of the first base layer 101 and the second base layer 103 may include polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. Each of the first barrier layer 102 and the second barrier layer 104 may include an inorganic insulating material, such as silicon oxide, silicon nitride, or silicon oxynitride.

The pixel driving circuit portion PC may be arranged on the substrate 100. The buffer layer 111 may be arranged on the substrate 100, and the pixel driving circuit portion PC may be arranged on the buffer layer 111. The buffer layer 111 may include an inorganic insulating material, such as silicon oxide, silicon nitride, and silicon oxynitride.

A thin-film transistor TFT may include a semiconductor layer Act, a gate electrode GE, a source electrode SE, and a drain electrode DE. FIG. 12 illustrates a top-gate type in which the gate electrode GE is arranged on the semiconductor layer Act with a gate insulating layer 113 therebetween. However, according to another embodiment, the thin-film transistor TFT may include a bottom-gate type.

The semiconductor layer Act may include polysilicon. Alternatively, the semiconductor layer Act may include amorphous silicon, an oxide semiconductor, an organic semiconductor, or the like. The gate electrode GE may include a low-resistance metal material. The gate electrode GE may include a conductive material including Mo, Al, Cu, Ti, or the like and may include layers or a single layer including the materials described above.

The gate insulating layer 113 between the semiconductor layer Act and the gate electrode GE may include an inorganic insulating material, such as silicon oxide, silicon nitride, silicon oxynitride, aluminum oxide, titanium oxide, etc. The gate insulating layer 113 may include a single layer or layers including the materials described above.

The source electrode SE and the drain electrode DE may be arranged on the same layer as each other, for example, on a second interlayer insulating layer 117, and may include the same material as each other. The source electrode SE and the drain electrode DE may include a conductive material and may include layers or a single layer. The second interlayer insulating layer 117 may include an inorganic insulating material, such as silicon oxide, silicon nitride, silicon oxynitride, aluminum oxide, titanium oxide, etc., and may include a single layer or layers including the materials described above.

The storage capacitor Cst may include a first electrode CE1 and a second electrode CE2 overlapping each other with a first interlayer insulating layer 115 therebetween. The storage capacitor Cst may overlap the thin-film transistor TFT. With respect to this aspect, FIG. 12 illustrates that the gate electrode GE of the thin-film transistor TFT may correspond to the first electrode CE1 of the storage capacitor Cst. According to another embodiment, the storage capacitor Cst may not overlap the thin-film transistor TFT. The storage capacitor Cst may be covered by the second interlayer insulating layer 117. The second electrode CE2 of the storage capacitor Cst may include a conductive material and may include layers or a single layer. The first interlayer insulating layer 115 may be arranged between the gate insulating layer 113 and the second interlayer insulating layer 117. The first interlayer insulating layer 115 may include an inorganic insulating material, such as silicon oxide, silicon nitride, silicon oxynitride, aluminum oxide, titanium oxide, etc., and may include a single layer or layers including the materials described above.

An inorganic insulating material layer IOL on the substrate 100 may include, for example, the buffer layer 111, the gate insulating layer 113, the first interlayer insulating layer 115, and the second interlayer insulating layer 117.

A first organic insulating layer 119 may be arranged on the second interlayer insulating layer 117, and a second organic insulating layer 121 may be arranged on the first organic insulating layer 119. Each of the first organic insulating layer 119 and the second organic insulating layer 121 may include an organic insulating material, such as polyimide.

The second voltage line VSSL may be arranged on the second organic insulating layer 121, and a third organic insulating layer 123 may be arranged on the second organic insulating layer 121 and the second voltage line VSSL. The third organic insulating layer 123 may include an organic insulating material, such as polyimide. The second voltage line VSSL may include a conductive material and may include layers or a single layer.

The first electrode pad 241 may be arranged on the pixel driving circuit portion PC to be electrically connected to the pixel driving circuit portion PC. The first electrode pad 241 may be arranged on the third organic insulating layer 123. The first electrode pad 241 may be electrically connected to the thin-film transistor TFT through a first connection electrode CM1 between the first organic insulating layer 119 and the second organic insulating layer 121 and a second connection electrode CM2 between the second organic insulating layer 121 and the third organic insulating layer 123.

The second electrode pad 242 may be arranged on the pixel driving circuit portion PC to be electrically connected to a power voltage. The second electrode pad 242 may be arranged on the third organic insulating layer 123. The second electrode pad 242 may be connected to the second voltage line VSSL by passing through the third organic insulating layer 123.

The inorganic light-emitting diode 230 may be arranged on the first electrode pad 241 and the second electrode pad 242. The inorganic light-emitting diode 230 described above with reference to FIG. 7B may be arranged on the first electrode pad 241 and the second electrode pad 242, while being flipped. In a direction (for example, a +z direction) away from the substrate 100, the second semiconductor layer 232, the intermediate layer 233, the first semiconductor layer 231, and the first electrode 235 may be sequentially arranged. Also, in the direction (for example, the +z direction) away from the substrate 100, the second semiconductor layer 232 and the second electrode 238 may be sequentially arranged.

A first adhesive layer AD1 may be arranged between the inorganic light-emitting diode 230 and the first electrode pad 241. Also, the first adhesive layer AD1 may be arranged between the inorganic light-emitting diode 230 and the second electrode pad 242. The first adhesive layer AD1 may be integrally provided between the inorganic light-emitting diode 230 and the first electrode pad 241 and between the inorganic light-emitting diode 230 and the second electrode pad 242. For example, the first adhesive layer AD1 may include an optical clear adhesive.

The touch unit 200 may be arranged on the third organic insulating layer 123. The touch unit 200 may include the driving electrode TE (see FIG. 9), the first signal line SLL1 (see FIG. 9) connected to the driving electrode TE, the sensing electrode RE (see FIG. 9), the second signal line SLL2 (see FIG. 9) connected to the sensing electrode RE, and at least one insulating layer. The touch sensor TS (see FIG. 9) included in the touch unit 200 may sense an external input, for example, by a capacitance method. The touch unit 200 may include a first planarization layer 125, a second planarization layer 127, a first touch conductive layer MTL1, and a second touch conductive layer MTL2.

The first touch conductive layer MTL1 may be arranged on the pixel driving circuit portion PC and may include a first conductive pattern. The first touch conductive layer MTL1 may be arranged on the third organic insulating layer 123. The first touch conductive layer MTL1 may reduce the interference phenomenon between a signal generated below the first touch conductive layer MTL1 and the touch unit 200.

The first electrode pad 241, the second electrode pad 242, and the first touch conductive layer MTL1 may be arranged on the same layer to be apart from one another and may include the same material as one another. The first electrode pad 241, the second electrode pad 242, and the first touch conductive layer MTL1 may be simultaneously formed on the third organic insulating layer 123 in the same process. Thus, the manufacturing process of the display apparatus 1 may become simple.

Each of the first electrode pad 241, the second electrode pad 242, and the first touch conductive layer MTL1 may have a single-layered structure or a multi-layered stack structure. For example, each of the first electrode pad 241, the second electrode pad 242, and the first touch conductive layer MTL1 may include a metal layer or a transparent conductive layer. For example, each of the first electrode pad 241, the second electrode pad 242, and the first touch conductive layer MTL1 may include Mo, Ag, Ti, Cu, Al, and an alloy thereof. For example, each of the first electrode pad 241, the second electrode pad 242, and the first touch conductive layer MTL1 may include transparent conductive oxide, such as ITO, IZO, ZnO, ITZO, etc. Alternatively, each of the first electrode pad 241, the second electrode pad 242, and the first touch conductive layer MTL1 may include a conductive polymer, such as PEDOT, a metal nanowire, graphene, etc.

The first planarization layer 125 may be arranged on the inorganic light-emitting diode 230. The first planarization layer 125 may cover the first electrode pad 241, the second electrode pad 242, the first touch conductive layer MTL1, the first adhesive layer AD1, and the inorganic light-emitting diode 230.

A first connection portion CP1 may be arranged on the first planarization layer 125. The first connection portion CP1 may electrically connect the inorganic light-emitting diode 230 with the first electrode pad 241. The first connection portion CP1 may be connected to the first electrode 235 of the inorganic light-emitting diode 230. The first connection portion CP1 may pass through the first planarization layer 125 and may be connected to the first electrode pad 241.

A second connection portion CP2 may be arranged on the first planarization layer 125. The second connection portion CP2 may electrically connect the inorganic light-emitting diode 230 with the second electrode pad 242. The second connection portion CP2 may be connected to the second electrode 238 of the inorganic light-emitting diode 230. The second connection portion CP2 may pass through the first planarization layer 125 and may be connected to the second electrode pad 242.

The second touch conductive layer MTL2 may be arranged on the first planarization layer 125 and may include a second conductive pattern. The first conductive pattern and the second conductive pattern may form a touch sensor. The second touch conductive layer MTL2 may be electrically connected to the first touch conductive layer MTL1. The second touch conductive layer MTL2 may pass through the first planarization layer 125 and may be connected to the first touch conductive layer MTL1. The first connection portion CP1, the second connection portion CP2, and the second touch conductive layer MTL2 may be arranged on the same layer to be apart from one another and may include the same material as one another. The first connection portion CP1, the second connection portion CP2, and the second touch conductive layer MTL2 may be simultaneously formed on the first planarization layer 125 in the same process. Thus, the manufacturing process of the display apparatus 1 may become simple.

Each of the first connection portion CP1, the second connection portion CP2, and the second touch conductive layer MTL2 may have a single-layered structure or a multi-layered stack structure. For example, each of the first connection portion CP1, the second connection portion CP2, and the second touch conductive layer MTL2 may include a transparent conductive layer. For example, each of the first connection portion CP1, the second connection portion CP2, and the second touch conductive layer MTL2 may include transparent conductive oxide, such as ITO, IZO, ZnO, ITZO, etc. Alternatively, each of the first connection portion CP1, the second connection portion CP2, and the second touch conductive layer MTL2 may include a conductive polymer, such as PEDOT, a metal nano-wire, graphene, etc.

The second planarization layer 127 may be arranged on the first planarization layer 125. The second planarization layer 127 may cover the first connection portion CP1, the second connection portion CP2, and the second touch conductive layer MTL2. Each of the first planarization layer 125 and the second planarization layer 127 may include an organic material. The organic material may include at least one material selected from the group consisting of acryl-based resins, methacryl-based resins, polyisoprene, vinyl-based resins, epoxy-based resins, urethane-based resins, cellulose-based resins, and pherylene-based resins. Each of the first planarization layer 125 and the second planarization layer 127 may further include an inorganic material. The inorganic material may include at least one material selected from the group consisting of SiNₓ, AlN, ZrN, TiN, HfN, TaN, SiOₓ, Al₂O₃, TiO₂, SnO₂, CeO₂, SiON.

Referring to FIG. 11B, the first bridge portion 12 may include the plurality of lines WL electrically connected to the pixel driving circuit portions PC respectively arranged in the first island portions 11 adjacent to each other. As described above, the lines WL may include the signal lines (for example, the gate lines, the data lines, etc.) configured to provide an electrical signal to the transistor included in the pixel driving circuit portion PC of the first island portion 11 or the voltage lines (for example, the driving voltage line, the initialization voltage line, etc.) configured to provide a voltage to the transistor included in the pixel driving circuit portion PC of the first island portion 11. FIG. 11B illustrates that the plurality of lines WL, for example, first to third lines WL1 to WL3, are arranged on the first bridge portion 12. However, the disclosure is not limited thereto. According to another embodiment, one line WL may be arranged on the first bridge portion 12.

Referring to FIG. 12, the substrate 100 corresponding to the bridge area EAB may have substantially the same stack structure as the substrate 100 corresponding to the island area EAI, according to an embodiment. According to an embodiment, the substrate 100 corresponding to the bridge area EAB may include the first base layer 101, the first barrier layer 102, the second base layer 103, and the second barrier layer 104. According to another embodiment, the substrate 100 corresponding to the bridge area EAB may have a stack structure different from a stack structure of the substrate 100 corresponding to the island area EAI. The substrate 100 corresponding to the bridge area EAB may have the structure of the first base layer 101 and the second base layer 103.

According to an embodiment, the inorganic insulating material layer IOL may not be arranged on the substrate 100 and an insulating layer OL, the first organic insulating layer 119, and the second organic insulating layer 121 may be arranged on the substrate 100. The insulating layer OL may include an organic insulating material such as polyimide. According to an embodiment, the insulating layer OL may have a thickness corresponding to a thickness of the inorganic insulating material layer IOL. According to some embodiments, the insulating layer OL may be omitted.

The plurality of lines WL, for example, the first to third lines WL1 to WL3, may be arranged on different layers from one another, but may be electrically connected to the same pixel driving circuit portion PC. For example, the first line WL1 may be arranged between the second organic insulating layer 121 and the third organic insulating layer 123, the second line WL2 may be arranged between the first organic insulating layer 119 and the second organic insulating layer 121, and the third line WL3 may be arranged between the insulating layer OL and the first organic insulating layer 119. However, the disclosure is not limited thereto, and according to another embodiment, at least one of the first to third lines WL1 to WL3 may be arranged on the same layer.

A first shielding layer SHP1 may be arranged on the third organic insulating layer 123. The first shielding layer SHP1, the first electrode pad 241, the second electrode pad 242, and the first touch conductive layer MTL1 may be arranged on the same layer as one another to be apart from one another and may include the same material as one another. The first shielding layer SHP1, the first electrode pad 241, the second electrode pad 242, and the first touch conductive layer MTL1 may be simultaneously formed on the third organic insulating layer 123 in the same process. Thus, the manufacturing process of the display apparatus 1 may become simple.

The first shielding layer SHP1 may have a single-layered structure or a multi-layered stack structure. For example, the first shielding layer SHP1 may include a metal layer or a transparent conductive layer. For example, the first shielding layer SHP1 may include Mo, Ag, Ti, Cu, Al, and an alloy thereof. For example, the first shielding layer SHP1 may include transparent conductive oxide, such as ITO, IZO, ZnO, ITZO, etc. Alternatively, the first shielding layer SHP1 may include a conductive polymer, such as PEDOT, a metal nano-wire, graphene, etc.

The first planarization layer 125 may be arranged on the third organic insulating layer 123 to cover the first shielding layer SHP1. The second touch conductive layer MTL2 may be arranged on the first planarization layer 125. Also, the second planarization layer 127 may be arranged on the first planarization layer 125 to cover the second touch conductive layer MTL2.

Referring to FIGS. 9 and 12, the first touch conductive layer MTL1 and the second touch conductive layer MTL2 may have a mesh structure to transmit light emitted from the inorganic light-emitting diode 230. Here, the first touch conductive layer MTL1 and the second touch conductive layer MTL2 may be arranged not to overlap the inorganic light-emitting diode 230.

The first touch conductive layer MTL1 may include the second connection patterns SP2 for connecting the plurality of sensing electrodes RE. The first touch conductive layer MTL1 may be arranged in the plurality of island areas EAI and may be apart from the plurality of bridge areas EAB. That is, the first touch conductive layer MTL1 may not overlap the plurality of bridge areas EAB.

The second touch conductive layer MTL2 may include the plurality of sensing electrodes RE, the plurality of driving electrodes TE, and the first connection patterns SP1 for connecting the plurality of driving electrodes TE. The second touch conductive layer MTL2 may be arranged in each of the plurality of island areas EAI and the plurality of bridge areas EAB.

The plurality of driving electrodes TE may be connected to each other by the first connection patterns SP1 formed on the same layer as the plurality of driving electrodes TE, and the plurality of sensing electrodes RE may be connected to each other by the second connection patterns SP2 formed on a different layer from the plurality of sensing electrodes RE through a contact hole. According to an embodiment, the plurality of driving electrodes TE and the first connection patterns SP1 may be integrally formed.

The first shielding layer SHP1 may overlap the second conductive layer MTL2 arranged in the plurality of bridge areas EAB. The first shielding layer SHP1 may reduce the interference phenomenon between the touch unit 200 arranged on the first shielding layer SHP1 and the line WL arranged below the first shielding layer SHP1.

In this structure, at least a portion of the touch unit 200 may be arranged on the same layer as the inorganic light-emitting diode 230, and thus, the thickness of the display apparatus 1 may be reduced. Thus, the elongation rate and the durability of the display apparatus 1 may be improved.

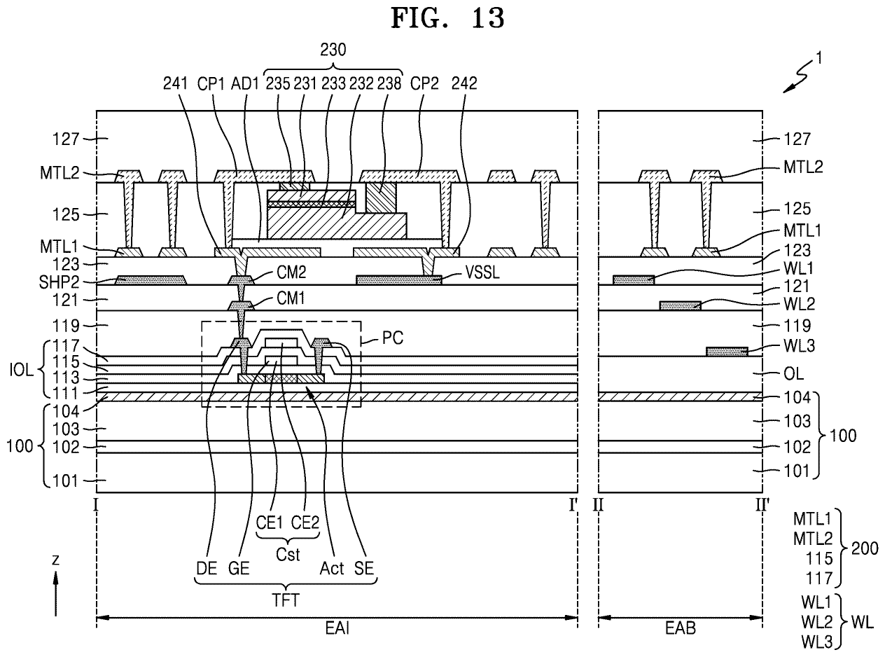

FIG. 13 is a schematic cross-sectional view of the display apparatus 1 according to an embodiment.

In detail, FIG. 13 is the cross-sectional view of the display apparatus 1, taken along line I-I′ of FIG. 11A and line II-II′ of FIG. 11B.

In FIG. 13, reference numerals that are the same as the reference numerals in FIG. 12 denote the same elements, and thus, their descriptions are not repeated.

Referring to FIG. 13, the substrate 100 corresponding to the island area EAI may include the first base layer 101, the first barrier layer 102, the second base layer 103, and the second barrier layer 104. The pixel driving circuit portion PC may be arranged on the substrate 100. The buffer layer 111 may be arranged on the substrate 100, and the pixel driving circuit portion PC may be arranged on the buffer layer 111. The thin-film transistor TFT may include the semiconductor layer Act, the gate electrode GE, the source electrode SE, and the drain electrode DE. The source electrode SE and the drain electrode DE may be arranged on the same layer as each other, for example, on the second interlayer insulating layer 117, and may include the same material as each other. The storage capacitor Cst may include the first electrode CE1 and the second electrode CE2 overlapping each other with the first interlayer insulating layer 115 therebetween.

The inorganic insulating material layer IOL on the substrate 100 may include, for example, the buffer layer 111, the gate insulating layer 113, the first interlayer insulating layer 115, and the second interlayer insulating layer 117. The first organic insulating layer 119 may be arranged on the second interlayer insulating layer 117, and the second organic insulating layer 121 may be arranged on the first organic insulating layer 119. The second voltage line VSSL may be arranged on the second organic insulating layer 121, and the third organic insulating layer 123 may be arranged on the second organic insulating layer 121 and the second voltage line VSSL.

The first electrode pad 241 may be arranged on the pixel driving circuit portion PC to be electrically connected to the pixel driving circuit portion PC. The first electrode pad 241 may be arranged on the third organic insulating layer 123. The first electrode pad 241 may be electrically connected to the thin-film transistor TFT through the first connection electrode CM1 between the first organic insulating layer 119 and the second organic insulating layer 121 and the second connection electrode CM2 between the second organic insulating layer 121 and the third organic insulating layer 123.

The second electrode pad 242 may be arranged on the pixel driving circuit portion PC to be electrically connected to the power voltage. The second electrode pad 242 may be arranged on the third organic insulating layer 123. The second electrode pad 242 may be connected to the second voltage line VSSL by passing through the third organic insulating layer 123.

The inorganic light-emitting diode 230 may be arranged on the first electrode pad 241 and the second electrode pad 242. The first adhesive layer AD1 may be arranged between the inorganic light-emitting diode 230 and the first electrode pad 241. Also, the first adhesive layer AD1 may be arranged between the inorganic light-emitting diode 230 and the second electrode pad 242.

The touch unit 200 may be arranged on the third organic insulating layer 123. The touch unit 200 may include the first planarization layer 125, the second planarization layer 127, the first touch conductive layer MTL1, and the second touch conductive layer MTL2. The first touch conductive layer MTL1 may be arranged on the pixel driving circuit portion PC and may include a first conductive pattern. The first touch conductive layer MTL1 may be arranged on the third organic insulating layer 123. The first electrode pad 241, the second electrode pad 242, and the first touch conductive layer MTL1 may be arranged on the same layer as one another to be apart from one another and may include the same material as one another. The first electrode pad 241, the second electrode pad 242, and the first touch conductive layer MTL1 may be simultaneously formed on the third organic insulating layer 123 in the same process. Thus, the manufacturing process of the display apparatus 1 may become simple.

The first planarization layer 125 may be arranged on the inorganic light-emitting diode 230. The first planarization layer 125 may cover the first electrode pad 241, the second electrode pad 242, the first touch conductive layer MTL1, the first adhesive layer AD1, and the inorganic light-emitting diode 230. The first connection portion CP1 may be arranged on the first planarization layer 125. The second connection portion CP2 may be arranged on the first planarization layer 125.

The second touch conductive layer MTL2 may be arranged on the first planarization layer 125 and may include the second conductive pattern. The second touch conductive layer MTL2 may be electrically connected to the first touch conductive layer MTL1. The second touch conductive layer MTL2 may pass through the first planarization layer 125 and may be connected to the first touch conductive layer MTL1. The second touch conductive layer MTL2 may be selectively connected to the first touch conductive layer MTL1. The first connection portion CP1, the second connection portion CP2, and the second touch conductive layer MTL2 may be arranged on the same layer as one another to be apart from one another and may include the same material as one another. The first connection portion CP1, the second connection portion CP2, and the second touch conductive layer MTL2 may be simultaneously formed on the first planarization layer 125 in the same process. Thus, the manufacturing process of the display apparatus 1 may become simple.

The second planarization layer 127 may be arranged on the first planarization layer 125. The second planarization layer 127 may cover the first connection portion CP1, the second connection portion CP2, and the second touch conductive layer MTL2. A second shielding layer SHP2 may be arranged between the first touch conductive layer MTL1 and the pixel driving circuit portion PC. The second shielding layer SHP2 may overlap the first touch conductive layer MTL1 arranged in the plurality of island areas EAI.

For example, as illustrated in FIG. 13, the second shielding layer SHP2 may be arranged on the second organic insulating layer 121, and the third organic insulating layer 123 may cover the second shielding layer SHP2. Alternatively, for example, unlike what is illustrated in FIG. 13, the second shielding layer SHP2 may be arranged on the first organic insulating layer 119, and the second organic insulating layer 121 may cover the second shielding layer SHP2.

The second shielding layer SHP2 may have a single-layered structure or a multi-layered stack structure. For example, the second shielding layer SHP2 may include a metal layer or a transparent conductive layer. For example, the second shielding layer SHP2 may include Mo, Ag, Ti, Cu, Al, and an alloy thereof. For example, the second shielding layer SHP2 may include transparent conductive oxide, such as ITO, IZO, ZnO, ITZO, etc. Alternatively, the second shielding layer SHP2 may include a conductive polymer, such as PEDOT, a metal nano-wire, graphene, etc. The second shielding layer SHP2 may reduce the interference phenomenon between a signal generated below the second shielding layer SHP2 and the touch unit 200.

The substrate 100 corresponding to the bridge area EAB may have a stack structure the same as a stack structure of the substrate 100 corresponding to the island area EAI. According to an embodiment, the substrate 100 corresponding to the bridge area EAB may include the first base layer 101, the first barrier layer 102, the second base layer 103, and the second barrier layer 104.

According to one or more embodiments, the inorganic insulating material layer IOL may not be arranged on the substrate 100 and the insulating layer OL, the first organic insulating layer 119, and the second organic insulating layer 121 may be arranged on the substrate 100. The plurality of lines WL, for example, the first to third lines WL1 to WL3, may be arranged on different layers from one another, but may be electrically connected to the same pixel driving circuit portion PC. The first touch conductive layer MTL1 may be arranged on the third organic insulating layer 123. The first touch conductive layer MTL1 may reduce the interference phenomenon between a signal generated before the first touch conductive layer MTL1 and the touch unit 200.

The first electrode pad 241, the second electrode pad 242, and the first touch conductive layer MTL1 may be arranged on the same layer as one another to be apart from one another and may include the same material as one another. The first electrode pad 241, the second electrode pad 242, and the first touch conductive layer MTL1 may be simultaneously formed on the third organic insulating layer 123 in the same process. Thus, the manufacturing process of the display apparatus 1 may become simple.

The first planarization layer 125 may be arranged on the third organic insulating layer 123 to cover the first touch conductive layer MTL1. The second touch conductive layer MTL2 may be arranged on the first planarization layer 125. Also, the second planarization layer 127 may be arranged on the first planarization layer 125 to cover the second touch conductive layer MTL2.

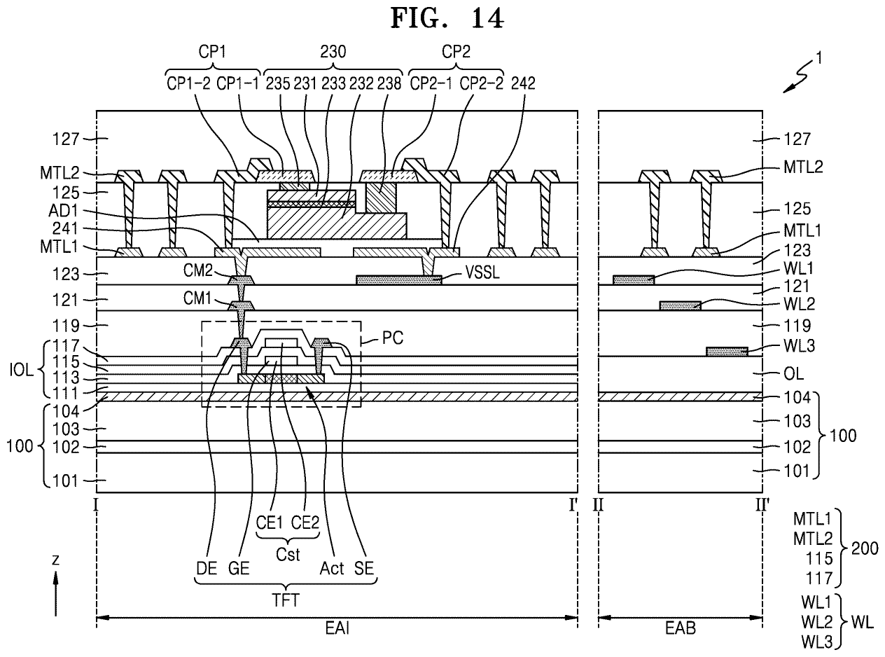

FIG. 14 is a schematic cross-sectional view of the display apparatus 1 according to an embodiment.

In detail, FIG. 14 is the cross-sectional view of the display apparatus 1, taken along line I-I′ of FIG. 11A and line II-II′ of FIG. 11B.

In FIG. 14, reference numerals that are the same as the reference numerals in FIG. 12 denote the same elements, and thus, their descriptions are not repeated.

Referring to FIG. 14, the substrate 100 corresponding to the island area EAI may include the first base layer 101, the first barrier layer 102, the second base layer 103, and the second barrier layer 104. The pixel driving circuit portion PC may be arranged on the substrate 100. The buffer layer 111 may be arranged on the substrate 100, and the pixel driving circuit portion PC may be arranged on the buffer layer 111. The thin-film transistor TFT may include the semiconductor layer Act, the gate electrode GE, the source electrode SE, and the drain electrode DE. The source electrode SE and the drain electrode DE may be arranged on the same layer as each other, for example, on the second interlayer insulating layer 117, and may include the same material as each other. The storage capacitor Cst may include the first electrode CE1 and the second electrode CE2 overlapping each other with the first interlayer insulating layer 115 therebetween.

The inorganic insulating material layer IOL on the substrate 100 may include, for example, the buffer layer 111, the gate insulating layer 113, the first interlayer insulating layer 115, and the second interlayer insulating layer 117. The first organic insulating layer 119 may be arranged on the second interlayer insulating layer 117, and the second organic insulating layer 121 may be arranged on the first organic insulating layer 119. The second voltage line VSSL may be arranged on the second organic insulating layer 121, and the third organic insulating layer 123 may be arranged on the second organic insulating layer 121 and the second voltage line VSSL.

The first electrode pad 241 may be arranged on the pixel driving circuit portion PC to be electrically connected to the pixel driving circuit portion PC. The first electrode pad 241 may be arranged on the third organic insulating layer 123. The first electrode pad 241 may be electrically connected to the thin-film transistor TFT through the first connection electrode CM1 between the first organic insulating layer 119 and the second organic insulating layer 121 and the second connection electrode CM2 between the second organic insulating layer 121 and the third organic insulating layer 123.

The second electrode pad 242 may be arranged on the pixel driving circuit portion PC to be electrically connected to the power voltage. The second electrode pad 242 may be arranged on the third organic insulating layer 123. The second electrode pad 242 may be connected to the second voltage line VSSL by passing through the third organic insulating layer 123.

The inorganic light-emitting diode 230 may be arranged on the first electrode pad 241 and the second electrode pad 242. The first adhesive layer AD1 may be arranged between the inorganic light-emitting diode 230 and the first electrode pad 241. Also, the first adhesive layer AD1 may be arranged between the inorganic light-emitting diode 230 and the second electrode pad 242.

The touch unit 200 may be arranged on the third organic insulating layer 123. The touch unit 200 may include the first planarization layer 125, the second planarization layer 127, the first touch conductive layer MTL1, and the second touch conductive layer MTL2. The first touch conductive layer MTL1 may be arranged on the pixel driving circuit portion PC and may include the first conductive pattern. The first touch conductive layer MTL1 may be arranged on the third organic insulating layer 123. The first electrode pad 241, the second electrode pad 242, and the first touch conductive layer MTL1 may be arranged on the same layer as one another to be apart from one another and may include the same material as one another. The first electrode pad 241, the second electrode pad 242, and the first touch conductive layer MTL1 may be simultaneously formed on the third organic insulating layer 123 in the same process. Thus, the manufacturing process of the display apparatus 1 may become simple.

The first planarization layer 125 may be arranged on the inorganic light-emitting diode 230. The first planarization layer 125 may cover the first electrode pad 241, the second electrode pad 242, the first touch conductive layer MTL1, the first adhesive layer AD1, and the inorganic light-emitting diode 230.

The first connection portion CP1 may be arranged on the first planarization layer 125. The first connection portion CP1 may electrically connect the inorganic light-emitting diode 230 with the first electrode pad 241.

The first connection portion CP1 may include a first-1 connection portion CP1-1 and a first-2 connection portion CP1-2. The first-1 connection portion CP1-1 may overlap the inorganic light-emitting diode 230 in a plan view. The first-1 connection portion CP1-1 may include a transparent material. For example, the first-1 connection portion CP1-1 may include transparent conductive oxide, such as ITO, IZO, ZnO, ITZO, etc.

The first-2 connection portion CP1-2 may electrically connect the first-1 connection portion CP1-1 with the first electrode pad 241. The first-2 connection portion CP1-2 may be connected to the first-1 connection portion CP1-1. The first-2 connection portion CP1-2 may pass through the first planarization layer 125 and may be connected to the first electrode pad 241. The first-2 connection portion CP1-2 may include the same material as the second touch conductive layer MTL2. The first-2 connection portion CP1-2 may include Mo, Ag, Ti, Cu, Al, and an alloy thereof.

The first-1 connection portion CP1-1 may include a transparent material, and thus, light emitted from the inorganic light-emitting diode 230 may pass through the first-1 connection portion CP1-1. Also, the first-2 connection portion CP1-2 may be non-transparent, but may include a material having a higher elongation rate than a material of the first-1 connection portion CP1-1. Thus, in this structure, the visibility of the inorganic light-emitting diode 230 may be secured, and the elongation rate of the display apparatus 1 may increase.

The second connection portion CP2 may be arranged on the first planarization layer 125. The second connection portion CP2 may electrically connect the inorganic light-emitting diode 230 with the second electrode pad 242. The second connection portion CP2 may include a second-1 connection portion CP2-1 and a second-2 connection portion CP2-2.

The second-1 connection portion CP2-1 may overlap the inorganic light-emitting diode 230 in a plan view. The second-1 connection portion CP2-1 may include a transparent material. For example, the second-1 connection portion CP2-1 may include transparent conductive oxide, such as ITO, IZO, ZnO, ITZO, etc.

The second-2 connection portion CP2-2 may electrically connect the second-1 connection portion CP2-1 with the second electrode pad 242. The second-2 connection portion CP2-2 may be connected to the second-1 connection portion CP2-1. The second-2 connection portion CP2-2 may pass through the first planarization layer 125 and may be connected to the second electrode pad 242. The second-2 connection portion CP2-2 may include the same material as the second touch conductive layer MTL2. The second-2 connection portion CP2-2 may include Mo, Ag, Ti, Cu, Al, and an alloy thereof.

The second-1 connection portion CP2-1 may include a transparent material, and thus, light emitted from the inorganic light-emitting diode 230 may pass through the second-1 connection portion CP2-1. Also, the second-2 connection portion CP2-2 may be non-transparent but may include a material having a higher elongation rate than a material of the second-1 connection portion CP2-1. Thus, in this structure, the visibility of the inorganic light-emitting diode 230 may be secured, and the elongation rate of the display apparatus 1 may increase.

The first-2 connection portion CP1-2, the second-2 connection portion CP2-2, and the second touch conductive layer MTL2 may be arranged on the same layer as one another to be apart from one another and may include the same material as one another. First, the first-1 connection portion CP1-1 and the second-1 connection portion CP2-1 may be formed on the third organic insulating layer 123, and then, the first-2 connection portion CP1-2, the second-2 connection portion CP2-2, and the second touch conductive layer MTL2 may be simultaneously formed. Thus, the manufacturing process of the display apparatus 1 may become simple.

The second touch conductive layer MTL2 may be arranged on the first planarization layer 125 and may include the second conductive pattern. The second touch conductive layer MTL2 may be electrically connected to the first touch conductive layer MTL1. The second touch conductive layer MTL2 may pass through the first planarization layer 125 and may be connected to the first touch conductive layer MTL1. The second touch conductive layer MTL2 may be selectively connected to the first touch conductive layer MTL1. The first connection portion CP1, the second connection portion CP2, and the second touch conductive layer MTL2 may be arranged on the same layer as one another to be apart from one another and may include the same material as one another.

The first connection portion CP1, the second connection portion CP2, and the second touch conductive layer MTL2 may be simultaneously formed on the first planarization layer 125 in the same process. Thus, the manufacturing process of the display apparatus 1 may become simple.

The second planarization layer 127 may be arranged on the first planarization layer 125. The second planarization layer 127 may cover the first connection portion CP1, the second connection portion CP2, and the second touch conductive layer MTL2.

The substrate 100 corresponding to the bridge area EAB may have a stack structure the same as a stack structure of the substrate 100 corresponding to the island area EAI. According to an embodiment, the substrate 100 corresponding to the bridge area EAB may include the first base layer 101, the first barrier layer 102, the second base layer 103, and the second barrier layer 104.

According to one or more embodiments, the inorganic insulating material layer IOL may not be arranged on the substrate 100, and the insulating layer OL, the first organic insulating layer 119, and the second organic insulating layer 121 may be arranged on the substrate 100. The plurality of lines WL, for example, the first to third lines WL1 to WL3, may be arranged on different layers from one another, but may be electrically connected to the same pixel driving circuit portion PC. The first touch conductive layer MTL1 may be arranged on the third organic insulating layer 123. The first touch conductive layer MTL1 may reduce the interference phenomenon between a signal generated below the first touch conductive layer MTL1 and the touch unit 200.

The first electrode pad 241, the second electrode pad 242, and the first touch conductive layer MTL1 may be arranged on the same layer as one another to be apart from one another and may include the same material as one another. The first electrode pad 241, the second electrode pad 242, and the first touch conductive layer MTL1 may be simultaneously formed on the third organic insulating layer 123 in the same process. Thus, the manufacturing process of the display apparatus 1 may become simple.

The first planarization layer 125 may be arranged on the third organic insulating layer 123 to cover the first touch conductive layer MTL1. The second touch conductive layer MTL2 may be arranged on the first planarization layer 125. Also, the second planarization layer 127 may be arranged on the first planarization layer 125 to cover the second touch conductive layer MTL2.

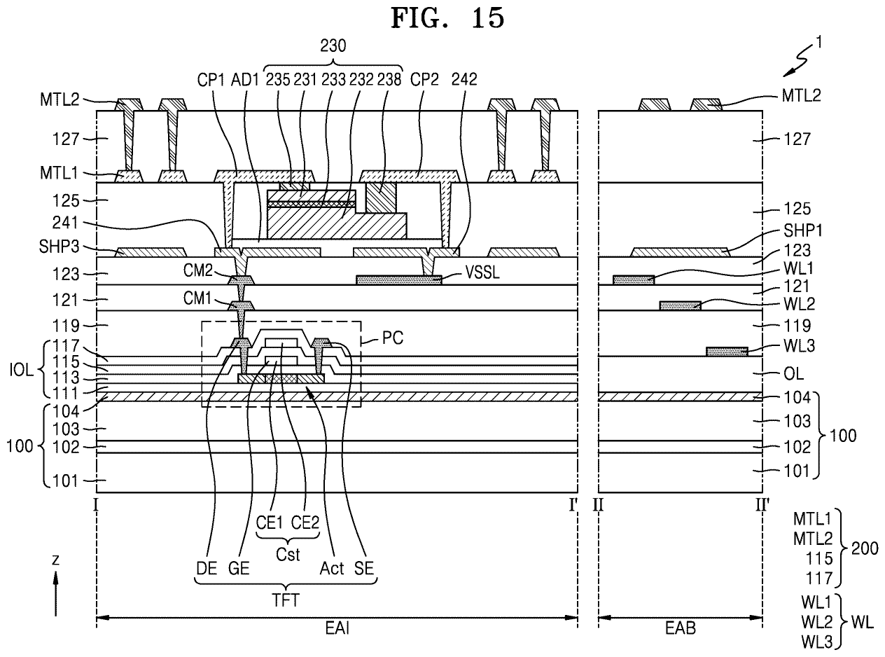

FIG. 15 is a schematic cross-sectional view of the display apparatus 1 according to an embodiment.

In detail, FIG. 15 is the cross-sectional view of the display apparatus 1, taken along line I-I′ of FIG. 11A and line II-II′ of FIG. 11B.

In FIG. 15, reference numerals that are the same as the reference numerals in FIG. 12 denote the same elements, and thus, their descriptions are not repeated.

Referring to FIG. 15, the substrate 100 corresponding to the island area EAI may include the first base layer 101, the first barrier layer 102, the second base layer 103, and the second barrier layer 104. The pixel driving circuit portion PC may be arranged on the substrate 100. The buffer layer 111 may be arranged on the substrate 100, and the pixel driving circuit portion PC may be arranged on the buffer layer 111. The thin-film transistor TFT may include the semiconductor layer Act, the gate electrode GE, the source electrode SE, and the drain electrode DE. The source electrode SE and the drain electrode DE may be arranged on the same layer as each other, for example, on the second interlayer insulating layer 117, and may include the same material as each other. The storage capacitor Cst may include the first electrode CE1 and the second electrode CE2 overlapping each other with the first interlayer insulating layer 115 therebetween.

The inorganic insulating material layer IOL on the substrate 100 may include, for example, the buffer layer 111, the gate insulating layer 113, the first interlayer insulating layer 115, and the second interlayer insulating layer 117. The first organic insulating layer 119 may be arranged on the second interlayer insulating layer 117, and the second organic insulating layer 121 may be arranged on the first organic insulating layer 119. The second voltage line VSSL may be arranged on the second organic insulating layer 121, and the third organic insulating layer 123 may be arranged on the second organic insulating layer 121 and the second voltage line VSSL.

The first electrode pad 241 may be arranged on the pixel driving circuit portion PC to be electrically connected to the pixel driving circuit portion PC. The first electrode pad 241 may be arranged on the third organic insulating layer 123. The first electrode pad 241 may be electrically connected to the thin-film transistor TFT through the first connection electrode CM1 between the first organic insulating layer 119 and the second organic insulating layer 121 and the second connection electrode CM2 between the second organic insulating layer 121 and the third organic insulating layer 123.

The second electrode pad 242 may be arranged on the pixel driving circuit portion PC to be electrically connected to the power voltage. The second electrode pad 242 may be arranged on the third organic insulating layer 123. The second electrode pad 242 may be connected to the second voltage line VSSL by passing through the third organic insulating layer 123.

The inorganic light-emitting diode 230 may be arranged on the first electrode pad 241 and the second electrode pad 242. The first adhesive layer AD1 may be arranged between the inorganic light-emitting diode 230 and the first electrode pad 241. Also, the first adhesive layer AD1 may be arranged between the inorganic light-emitting diode 230 and the second electrode pad 242.

The touch unit 200 may be arranged on the third organic insulating layer 123. The touch unit 200 may include the first planarization layer 125, the second planarization layer 127, the first touch conductive layer MTL1, and the second touch conductive layer MTL2.

The first planarization layer 125 may be arranged on the third organic insulating layer 123. The first planarization layer 125 may cover the first electrode pad 241, the second electrode pad 242, the inorganic light-emitting diode 230, and the first adhesive layer AD1. The first connection portion CP1 and the second connection portion CP2 may be arranged on the first planarization layer 125. Each of the first connection portion CP1 and the second connection portion CP2 may pass through the first planarization layer 125.

The first touch conductive layer MTL1 may be arranged on the pixel driving circuit portion PC and may include the first conductive pattern. The first touch conductive layer MTL1 may be arranged on the first planarization layer 125.

The first connection portion CP1, the second connection portion CP2, and the first touch conductive layer MTL1 may be arranged on the same layer as one another to be apart from one another and may include the same material as one another. The first connection portion CP1, the second connection portion CP2, and the first touch conductive layer MTL1 may be simultaneously formed on the first planarization layer 125 in the same process. Thus, the manufacturing process of the display apparatus 1 may become simple.

The second planarization layer 127 may be arranged on the first planarization layer 125. The second planarization layer 127 may cover the first connection portion CP1, the second connection portion CP2, and the first touch conductive layer MTL1.

The second touch conductive layer MTL2 may be arranged on the second planarization layer 127 and may include the second conductive pattern. The second touch conductive layer MTL2 may be electrically connected to the first touch conductive layer MTL1. The second touch conductive layer MTL2 may pass through the second planarization layer 127 and may be connected to the first touch conductive layer MTL1.

A third shielding layer SHP3 may be arranged between the first touch conductive layer MTL1 and the pixel driving circuit portion PC. For example, the third shielding layer SHP3 may be arranged on the third organic insulating layer 123. For example, the first planarization layer 125 may cover the third shielding layer SHP3.

The third shielding layer SHP3 may overlap the first touch conductive layer MTL1 arranged in the plurality of island areas EAI. The third shielding layer SHP3 may reduce the interference phenomenon between a signal generated below the third shielding layer SHP3 and the touch unit 200.

The first electrode pad 241, the second electrode pad 242, and the third shielding layer SHP3 may be arranged on the same layer as one another to be apart from one another and may include the same material as one another. The first electrode pad 241, the second electrode pad 242, and the third shielding layer SHP3 may be simultaneously formed on the third organic insulating layer 123 in the same process. Thus, the manufacturing process of the display apparatus 1 may become simple.

The substrate 100 corresponding to the bridge area EAB may have a stack structure the same as a stack structure of the substrate 100 corresponding to the island area EAI. According to an embodiment, the substrate 100 corresponding to the bridge area EAB may include the first base layer 101, the first barrier layer 102, the second base layer 103, and the second barrier layer 104.

According to one or more embodiments, the inorganic insulating material layer IOL may not be arranged on the substrate 100, and the insulating layer OL, the first organic insulating layer 119, and the second organic insulating layer 121 may be arranged on the substrate 100. The plurality of lines WL, for example, the first to third lines WL1 to WL3, may be arranged on different layers from one another, but may be electrically connected to the same pixel driving circuit portion PC.

The first shielding layer SHP1 may be arranged on the third organic insulating layer 123. The first shielding layer SHP1, the first electrode pad 241, the second electrode pad 242, and the third shielding layer SHP3 may be arranged on the same layer as one another to be apart from one another and may include the same material as one another. The first shielding layer SHP1, the first electrode pad 241, the second electrode pad 242, and the third shielding layer MTL3 may be simultaneously formed on the third organic insulating layer 123 in the same process. Thus, the manufacturing process of the display apparatus 1 may become simple.

The first planarization layer 125 may be arranged on the third organic insulating layer 123 to cover the first shielding layer SHP1. The second planarization layer 127 may be arranged on the first planarization layer 125. The second touch conductive layer MTL2 may be arranged on the second planarization layer 127.

In this structure, the second touch conductive layer MTL2 may be arranged in each of the plurality of island areas EAI and the plurality of bridge areas EAB. Also, the first touch conductive layer MTL1 may be arranged in the plurality of island areas EAI and may be apart from the plurality of bridge areas EAB. The first touch conductive layer MTL1 may not be arranged in the plurality of bridge areas EAB, and thus, the elongation rate of the display apparatus 1 may be improved in the bridge area EAB.

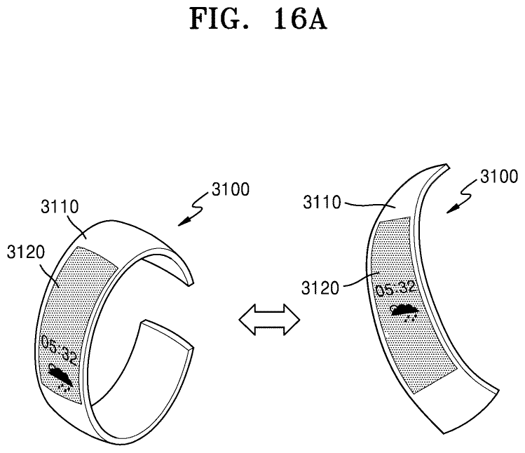

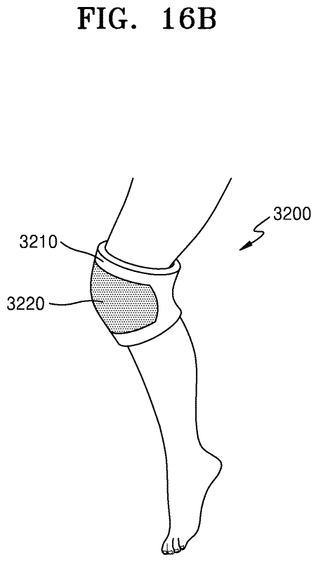

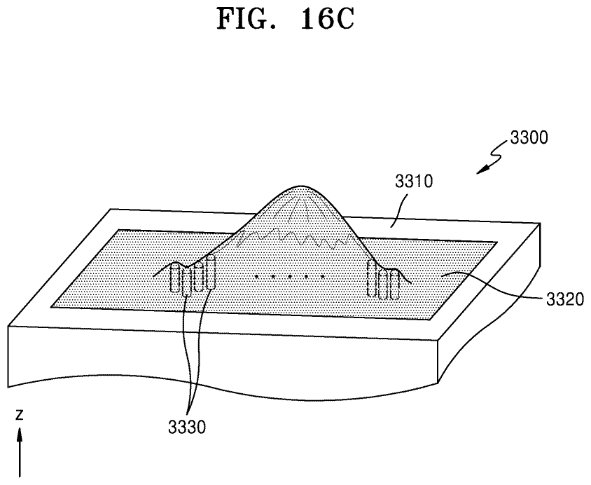

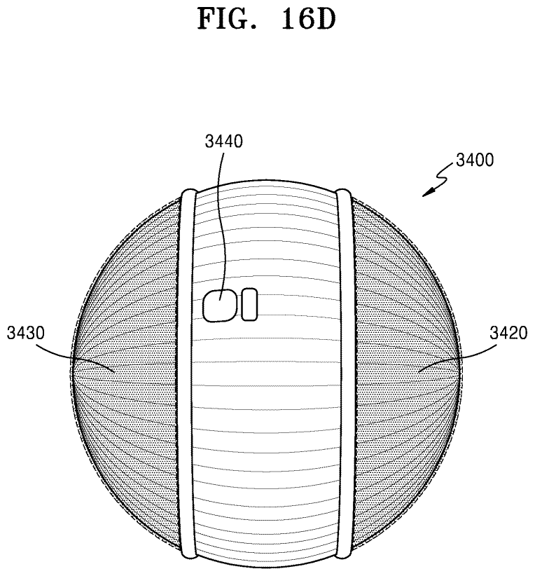

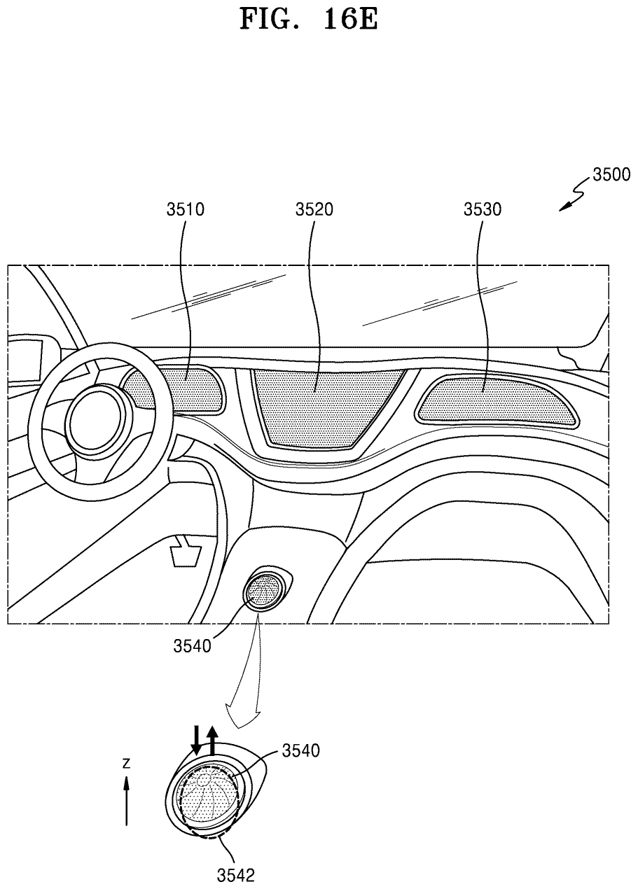

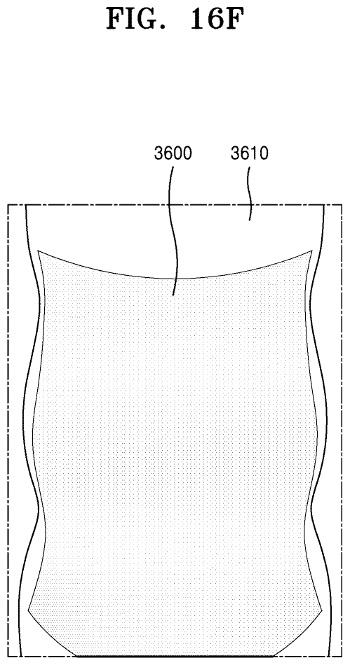

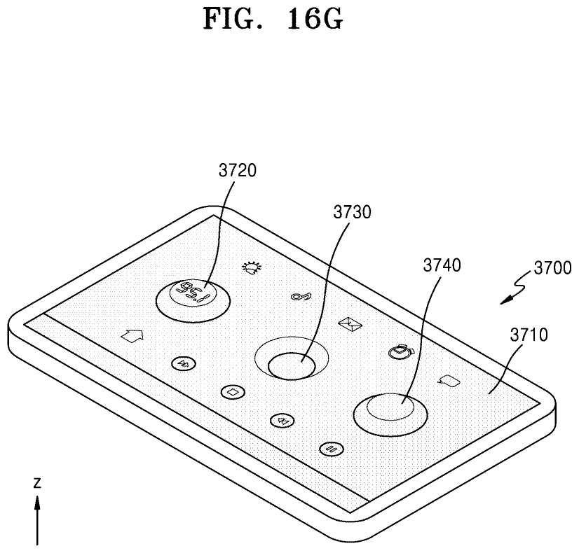

FIGS. 16A to 16G are schematic perspective views of electronic devices each including the display apparatus 1 according to an embodiment.

The display apparatus 1 according to the embodiments described above may be used for various electronic devices capable of providing an image. Here, the electronic device may indicate a device using electricity and capable of providing a certain image.

Referring to FIG. 16A, the display apparatus according to an embodiment may be used for a wearable electronic device 3100 which may be worn on a part of a human body of a user. The wearable electronic device 3100 may include a body 3110 and a display 3120 provided in the body 3110. The display apparatus according to embodiments may be used as the display 3120 of the wearable electronic device 3100. The wearable electronic device 3100 may be changed, as illustrated in FIG. 16A. According to an embodiment, according to selection of a user, the wearable electronic device 3100 may be used as a smart watch or a smartphone.

FIG. 16B illustrates a medical electronic device 3200. According to an embodiment, the medical electronic device 3200 may include a body 3210 and an emission portion 3220. The display apparatus according to embodiments may be used as the emission portion 3220 of the medical electronic device 3200. The emission portion 3220 may emit light of a certain wavelength band (for example, infrared rays, visible rays, etc.) to a human body of a patient. According to an embodiment, the body 3210 may include a flexible fiber material and may have a structure that is wearable on a human body of a user of the emission portion.

FIG. 16C illustrates an educational electronic device 3300. According to an embodiment, the educational electronic device may include a display 3320 provided in a frame 3310. The display 3320 may use the display apparatus according to embodiments. An image such as the sea swelling with waves, mountains covered with snow, volcanoes with flowing flames, or the like may be provided through the display 3320, and in this case, the display 3320 may be stretched in a height direction (for example, a z direction) by reflecting the height of the waves, mountains, or volcanoes. According to some embodiments, a portion of the display 3320 may have a height that is sequentially variable along a direction in which the flames flow, thereby three-dimensionally showing the movement of the flames. The educational electronic device 3300 may include a plurality of pins (or strokes) 3330 arranged at a rear surface of the display 3320 so that the display 3320 may be stretched in a height direction. As the pins 3330 move in a third direction (for example, the z direction or a −z direction), an image represented by the display 3320 may be realized to have a three-dimensional height. FIG. 16C illustrates the educational electronic device 3300. However, the described usage is not limited thereto and may be applied to all devices providing certain image information.

It is described that the electronic devices illustrated in FIGS. 16A to 16C may have variable shapes. However, the disclosure is not limited thereto. As described according to embodiments below, the display apparatus according to embodiments may be used for an electronic device having a fixed portion (for example, a screen) configured to display an image.

FIG. 16D illustrates a robot 3400 as another electronic device according to an embodiment. The robot 3400 may recognize a movement or an object by using a camera 3440 and may display a certain image for a user through displays 3420 and 3430. According to some embodiments, the display apparatus according to embodiments may be stretched in various directions as described above, and thus, may be assembled into a body frame having a semicircular shape. Thus, the robot 3400 may include the displays 3420 and 3430 having semicircular shapes.

FIG. 16E illustrates a vehicle display apparatus 3500 as an electronic device according to an embodiment. The vehicle display apparatus 3500 may include a cluster 3510, a center information display (CID) 3520, and/or a co-driver display 3530. The display apparatus according to embodiments may be stretched in various directions, and thus, may not be limited by the shape of an internal frame of a vehicle and may be used for the cluster 3510, the CID 3520, and/or the co-driver display 3530.

FIG. 16E illustrates that the cluster 3510, the CID 3520, and/or the co-driver display 3530 are separate devices from each other. However, the disclosure is not limited thereto. According to another embodiment, two or more selected from among the cluster 3510, the CID 3520, and the co-driver display 3530 may be integrally connected.

According to some embodiments, the vehicle display apparatus 3500 may include a button 3540 configured to display a certain image. With reference to an enlarged view of FIG. 16E, the button 3540 having a semicircular shape may include an object 3542 providing a sense of use of a button by moving in a z direction or a −z direction and a display apparatus arranged above the object 3542. According some embodiments, when the object 3542 has a three-dimensionally round surface, the display apparatus may also have a three-dimensionally round surface.

FIG. 16F illustrates that the electronic device according to an embodiment may correspond to an electronic device 3600 for advertisement or exhibition. According to some embodiments, the electronic device 3600 for advertisement or exhibition may be mounted on a structure 3610 that is fixed, such as a wall or a pillar. When the structure 3610 includes a concavo-convex surface as illustrated in FIG. 16F, the electronic device 3600 for advertisement or exhibition may also be arranged along the concavo-convex surface of the structure 3610. According to some embodiments, the electronic device 3600 for advertisement or exhibition may be mounted on the structure 3610 by using a thermal contraction film, etc.

FIG. 16G illustrates that the electronic device according to an embodiment corresponds to a controller 3700. The controller 3700 may include an image-type button. For example, the controller 3700 may include first to third button areas 3720, 3730, and 3740 in which portions of a display 3710, protrude in a z direction or protrude in a −z direction (or are recessed from the z direction). According to some embodiments, the first and third button areas 3720 and 3740 may protrude in the z direction, and the second button area 3730 may protrude in the −z direction (or may be recessed from the z direction).

A method of fabricating a display apparatus is also provided.

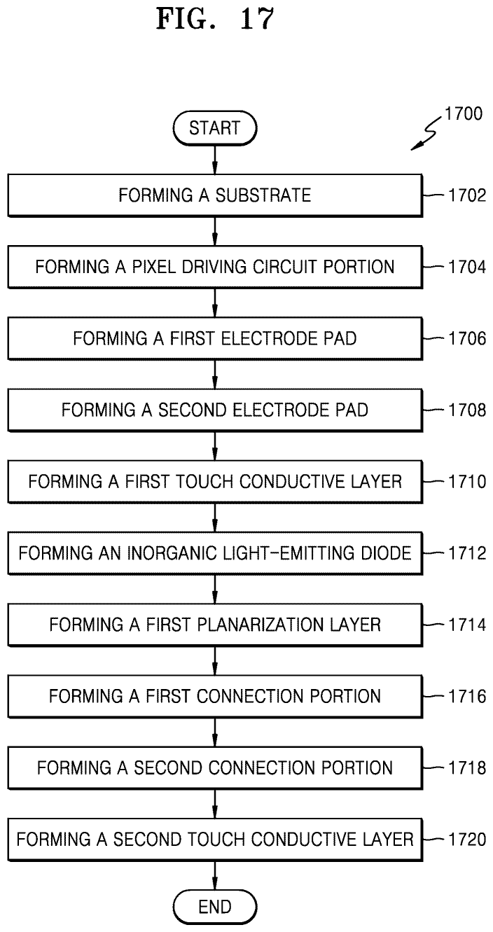

FIG. 17 illustrates a flow chart of a method 1700 for fabricating a display apparatus, such as the display apparatus 1 or any of the other display apparatuses described herein. At operation 1702, the method 1700 includes forming a substrate. At operation 1704, the method 1700 includes forming a pixel driving circuit portion arranged on the substrate. At operation 1706, the method 1700 includes forming a first electrode pad arranged on the pixel driving circuit portion to be electrically connected to the pixel driving circuit portion. At operation 1708, the method 1700 includes forming a second electrode pad arranged on the pixel driving circuit portion to be electrically connected to a power voltage. At operation 1710, the method 1700 includes forming a first touch conductive layer arranged on the pixel driving circuit portion and comprising a first conductive pattern. At operation 1712, the method 1700 includes forming an inorganic light-emitting diode arranged on the first electrode pad and the second electrode pad. At operation 1714, the method 1700 includes forming a first planarization layer arranged on the inorganic light-emitting diode. At operation 1716, the method 1700 includes forming a first connection portion arranged on the first planarization layer and electrically connecting the inorganic light-emitting diode to the first electrode pad. At operation 1718, the method 1700 includes forming a second connection portion arranged on the first planarization layer and electrically connecting the inorganic light-emitting diode to the second electrode pad. At operation 1720, the method 1700 includes forming a second touch conductive layer arranged on the first planarization layer to be electrically connected to the first touch conductive layer and comprising a second conductive pattern.

According to an embodiment, a display apparatus which may have increased elongation rate and may be stretched in various directions may be provided. However, the scope of the disclosure is not limited by these effects.

Effects of the one or more of the embodiments described above are not limited to the effects described above, and other effects that not are described may be clearly understood by one of ordinary skill in the art from the disclosure of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising a plurality of island areas each arranged to be spaced apart from each other and a plurality of bridge areas connecting the plurality of island areas, the display apparatus further comprising:
a substrate;
a pixel driving circuit portion arranged on the substrate;
a first electrode pad arranged on the pixel driving circuit portion to be electrically connected to the pixel driving circuit portion;
a second electrode pad arranged on the pixel driving circuit portion to be electrically connected to a power voltage;
a first touch conductive layer arranged on the pixel driving circuit portion and comprising a first conductive pattern;
an inorganic light-emitting diode arranged on the first electrode pad and the second electrode pad;
a first planarization layer arranged on the inorganic light-emitting diode;
a first connection portion arranged on the first planarization layer and electrically connecting the inorganic light-emitting diode to the first electrode pad;
a second connection portion arranged on the first planarization layer and electrically connecting the inorganic light-emitting diode to the second electrode pad; and
a second touch conductive layer arranged on the first planarization layer to be electrically connected to the first touch conductive layer and comprising a second conductive pattern.

2. The display apparatus of claim 1, wherein the first electrode pad, the second electrode pad, and the first touch conductive layer are arranged on a same layer and comprise a same material.

3. The display apparatus of claim 1, wherein the first connection portion, the second connection portion, and the second touch conductive layer are arranged on a same layer and comprise a same material.

4. The display apparatus of claim 1, wherein each of the first connection portion, the second connection portion, and the second touch conductive layer passes through the first planarization layer.

5. The display apparatus of claim 1, wherein the second touch conductive layer is arranged in each of the plurality of island areas and the plurality of bridge areas.

6. The display apparatus of claim 5, wherein the first touch conductive layer is arranged in the plurality of island areas and is apart from the plurality of bridge areas.

7. The display apparatus of claim 6, further comprising a first shielding layer arranged on a same layer as the first touch conductive layer and overlapping the second touch conductive layer arranged in the plurality of bridge areas.

8. The display apparatus of claim 7, wherein the first shielding layer and the first touch conductive layer comprise a same material.

9. The display apparatus of claim 1, wherein the first touch conductive layer is arranged in each of the plurality of island areas and the plurality of bridge areas.

10. The display apparatus of claim 1, further comprising a second shielding layer arranged between the first touch conductive layer and the pixel driving circuit portion and overlapping the first touch conductive layer arranged in the plurality of island areas.

11. The display apparatus of claim 1, wherein the first connection portion comprises:
a first-1 connection portion overlapping the inorganic light-emitting diode in a plan view and comprising a transparent material; and
a first-2 connection portion electrically connecting the first-1 connection portion to the first electrode pad and comprising a same material as the second touch conductive layer.

12. The display apparatus of claim 1, wherein the second connection portion comprises:
a second-1 connection portion overlapping the inorganic light-emitting diode in a plan view and comprising a transparent material; and
a second-2 connection portion electrically connecting the second-1 connection portion to the second electrode pad and comprising a same material as the second touch conductive layer.

13. An electronic device comprising a display apparatus which comprises a plurality of island areas each arranged to be spaced apart from each other and a plurality of bridge areas connecting the plurality of island areas and is stretchable,
the display apparatus further comprising:
a substrate;
a pixel driving circuit portion arranged on the substrate;
a first electrode pad arranged on the pixel driving circuit portion to be electrically connected to the pixel driving circuit portion;
a second electrode pad arranged on the pixel driving circuit portion to be electrically connected to a power voltage;
an inorganic light-emitting diode arranged on the first electrode pad and the second electrode pad;
a first planarization layer arranged on the inorganic light-emitting diode;
a first connection portion arranged on the first planarization layer and electrically connecting the inorganic light-emitting diode to the first electrode pad;
a second connection portion arranged on the first planarization layer and electrically connecting the inorganic light-emitting diode to the second electrode pad;
a first touch conductive layer arranged on the first planarization layer and comprising a first conductive pattern;
a second planarization layer arranged on the first touch conductive layer; and
a second touch conductive layer arranged on the second planarization layer to be electrically connected to the first touch conductive layer and comprising a second conductive pattern.

14. The electronic device of claim 13, wherein the first connection portion, the second connection portion, and the first touch conductive layer are arranged on a same layer and comprise a same material.

15. The electronic device of claim 13, wherein each of the first connection portion and the second connection portion passes through the first planarization layer.

16. The electronic device of claim 13, wherein the second touch conductive layer is arranged in each of the plurality of island areas and the plurality of bridge areas.

17. The electronic device of claim 16, wherein the first touch conductive layer is arranged in the plurality of island areas and is apart from the plurality of bridge areas.

18. The electronic device of claim 17, wherein the display apparatus further comprises a first shielding layer arranged on a same layer as each of the first electrode pad and the second electrode pad and overlapping the second touch conductive layer arranged in the plurality of bridge areas.

19. The electronic device of claim 18, wherein the first shielding layer comprises a same material as each of the first electrode pad and the second electrode pad.

20. A method of manufacturing a display apparatus, the method comprising:
forming a substrate;
forming a pixel driving circuit portion arranged on the substrate;
forming a first electrode pad arranged on the pixel driving circuit portion to be electrically connected to the pixel driving circuit portion;
forming a second electrode pad arranged on the pixel driving circuit portion to be electrically connected to a power voltage;
forming a first touch conductive layer arranged on the pixel driving circuit portion and comprising a first conductive pattern;
forming an inorganic light-emitting diode arranged on the first electrode pad and the second electrode pad;
forming a first planarization layer arranged on the inorganic light-emitting diode;
forming a first connection portion arranged on the first planarization layer and electrically connecting the inorganic light-emitting diode to the first electrode pad;
forming a second connection portion arranged on the first planarization layer and electrically connecting the inorganic light-emitting diode to the second electrode pad; and
forming a second touch conductive layer arranged on the first planarization layer to be electrically connected to the first touch conductive layer and comprising a second conductive pattern.
